(19) United States
(12) Patent Application Publication
(10) Pub. No.: US 2023/0265558 A1
(43) Pub. Date: Aug. 24, 2023

(54) ATOMIC LAYER DEPOSITION APPARATUS AND ATOMIC LAYER DEPOSITION METHOD USING THE SAME

(71) Applicant: Samsung Display Co., LTD., Yongin-si (KR)

(72) Inventors: Choel Min JANG, Seoul (KR); Myung Soo HUH, Suwon-si (KR); Jung Gon KIM, Hwaseong-si (KR); Min Gyu PARK, Cheonan-si (KR); Eun JUNG, Uiwang-si (KR)

(21) Appl. No.: 17/993,147

(22) Filed: Nov. 23, 2022

(30) Foreign Application Priority Data
Feb. 22, 2022 (KR) 10-2022-0022633

(51) Int. Cl. C23C 16/455

(52) U.S. Cl. CPC C23C 16/45504; C23C 16/45544

(57) ABSTRACT

An atomic layer deposition apparatus includes a substrate support which supports a substrate; a process module on the substrate support; a first gas pipe which supplies a first gas to the process module; a second gas pipe which supplies a second gas to the process module; and an exhaust part which discharges the first and second gases supplied to the process module. The process module includes: a first gas supply flow path portion connected to the first gas pipe; a second gas supply flow path portion under the first gas supply flow path portion and connected to the second gas pipe; and a gas exhaust flow path portion connected to the exhaust part. The gas exhaust flow path is spaced apart from the first and second gas supply flow path portions with the substrate therebetween, and the first and second gases pass through a process area in a laminar flow.

This application claims priority to Korean Patent Application No. 10-2022-0022633, filed on Feb. 22, 2022, and all the benefits accruing therefrom under 35 U.S.C. § 119, the content of which in its entirety is herein incorporated by reference.

### BACKGROUND

### 1. Field

The disclosure relates to an atomic layer deposition apparatus and an atomic layer deposition method using the atomic layer deposition apparatus.

### 2. Description of the Related Art

Semiconductor devices, display devices, and other electronic devices include a plurality of thin films. Among various methods for forming a plurality of thin films, a vapor deposition method is widely used.

The vapor deposition method uses one or more gases as a raw material for forming a thin film. The vapor deposition method include chemical vapor deposition (CVD), physical vapor deposition (PVD), and atomic layer deposition (ALD).

Among vapor deposition method, the atomic layer deposition method is a method of forming a thin film through a surface reaction while injecting a reaction source and a reaction gas in a time division manner. The atomic layer deposition method may show high coating properties and uniformity. Accordingly, it is possible to form a thin film through a surface reaction by sequentially injecting a reaction source and a reaction gas to a substrate surface using the atomic layer deposition method.

### SUMMARY

Embodiments of the disclosure provide an atomic layer deposition apparatus with improved processability.

Embodiments of the disclosure also provide an atomic layer deposition method with improved processability.

According to an embodiment of the disclosure, an atomic layer deposition apparatus includes a substrate support which supports a substrate placed thereon; a process module disposed on the substrate support; a first gas pipe which supplies a first gas to the process module; a second gas pipe which supplies a second gas to the process module; and an exhaust part which discharges the first gas and the second gas supplied to the process module, where the process module includes: a first gas supply flow path portion connected to the first gas pipe; a second gas supply flow path portion disposed under the first gas supply flow path portion and connected to the second gas pipe; and a gas exhaust flow path portion connected to the exhaust part, where the gas exhaust flow path portion is spaced apart from the first gas supply flow path portion and the second gas supply flow path portion with the substrate interposed therebetween, and the first gas and the second gas pass through a process area, which is defined as a space between the gas exhaust flow path portion and the first and second gas supply flow path portions, in a laminar flow.

In an embodiment, the first gas supply flow path portion and the second gas supply flow path portion may be spaced apart from each other with a flow path partitioning portion interposed therebetween.

In an embodiment, the first gas supply flow path portion may become wider along a direction in which the first gas flows.

In an embodiment, the first gas supply flow path portion may be provided in plural, and the first gas supply flow path portions may be spaced apart from each other. In such an embodiment, the process module may further include a first gas distribution flow path portion disposed on and connected to the first gas supply flow path portions, where the first gas distribution flow path portion may divide the first gas into a plurality of flows, and supply the plurality of flows of the first gas to the first gas supply flow path portions, respectively. In such an embodiment, the first gas pipe may be connected to the first gas distribution flow path portion, the first gas distribution flow path portion may include a plurality of first through-holes corresponding to the first gas supply flow path portions, respectively, and the first through-holes may be connected to the first gas supply flow path portions, respectively.

In an embodiment, the second gas supply flow path portion may be provided in plural, and the second gas supply flow path portions may be spaced apart from each other. In such an embodiment, the process module may further include a second gas distribution flow path portion disposed under and connected to the second gas supply flow path portions, where the second gas distribution flow path portion may divide the second gas into a plurality of flows, and supply the plurality of flows of the second gas to the second gas supply flow path portions, respectively. In such an embodiment, the second gas pipe may be connected to the second gas distribution flow path portion, the second gas distribution flow path portion may include a plurality of second through-holes corresponding to the second gas supply flow path portions, respectively, and the second through-holes may be connected to the second gas supply flow path portions, respectively.

In an embodiment, the second gas supply flow path portions may become wider along a direction in which the second gas flows.

In an embodiment, the atomic layer deposition apparatus may further include a plasma generator disposed on the process area.

In an embodiment, the first gas pipe and the second gas pipe may be disposed on the first gas supply flow path portion, and a length of the second gas pipe may be greater than a length of the first gas pipe.

In an embodiment, the atomic layer deposition apparatus may further include a gas merging flow path portion disposed on the gas exhaust flow path portion, where the gas merging flow path portion may concentrate the first gas or the second gas passing through the gas exhaust flow path portion, where the exhaust part may be connected to the gas merging flow path portion.

In an embodiment, the gas merging flow path portion may become narrower along the direction in which the first gas and the second gas flow.

In an embodiment, a thickness of the first gas supply flow path portion and a thickness of the second gas supply flow path portion may be smaller than a thickness of the gas exhaust flow path portion.

In an embodiment, a sum of the thickness of the first gas supply flow path portion, the thickness of the second gas supply flow path portion, and a thickness of the flow path partitioning portion may be substantially the same as the thickness of the gas exhaust flow path portion.

In an embodiment, the atomic layer deposition apparatus may further include an upper shielding plate disposed on the first gas supply flow path portion, where the first gas supply flow path portion may form a first gas flow path with the upper shielding plate, and the second gas supply flow path may form a second gas flow path with the substrate support.

In an embodiment, the first gas may pass through the first gas flow path, the second gas may pass through the second gas flow path, and the second gas may have a smaller molecular weight than the first gas.

According to another embodiment of the disclosure, an atomic layer deposition method includes preparing an atomic layer deposition apparatus including a first gas supply flow path portion to which a first gas and a first purge gas are supplied, a second gas supply flow path portion to which a second gas and a second purge gas are supplied, and a gas exhaust flow path portion from which the first gas and the second gas are discharged; supplying the first gas to the first gas supply flow path portion; supplying the first purge gas to the first gas supply flow path portion and stopping the supplying the first gas to the first gas supply flow path portion to the first gas supply flow path portion; supplying the second gas to the second gas supply flow path portion; and supplying the second purge gas to the second gas supply flow path portion and stopping the supplying the second gas to the second gas supply flow path portion, where the second gas supply flow path portion is disposed under the first gas supply flow path portion, and the gas exhaust flow path portion and the first and second gas supply flow path portions are spaced apart from each other.

In an embodiment, the first gas and the second gas may pass through a process area, which is defined as a space between the gas exhaust flow path portion and the first and second gas supply flow path portions, in a laminar flow pattern.

In an embodiment, both the first gas and the first purge gas may be present in the process area.

In an embodiment, the first gas, the first purge gas, the second gas, and the second purge gas may all be present in the process area.

In an embodiment, the atomic layer deposition method may further include supplying the second purge gas to the second gas supply flow path portion, where the supplying the first gas to the first gas supply flow path portion and the supplying the second purge gas to the second gas supply flow path portion may be simultaneously performed.

In an embodiment, the atomic layer deposition method may further include supplying the first purge gas to the first gas supply flow path portion, where the supplying the second gas to the second gas supply flow path portion and the supplying the first purge gas to the first gas supply flow path portion may be simultaneously performed.

### BRIEF DESCRIPTION OF THE DRAWINGS

These and/or other features of embodiments of the invention will become apparent and more readily appreciated from the following description of the embodiments, taken in conjunction with the accompanying drawings in which:

FIG. 1 is a perspective view illustrating an atomic layer deposition apparatus according to an embodiment in a state before performing a process;

FIG. 2 is an exploded perspective view of the atomic layer deposition apparatus of FIG. 1;

FIG. 3 is an exploded perspective view of a process module of the atomic layer deposition apparatus of FIG. 1;

FIG. 4 is a perspective view of a first main flow path member of FIG. 3;

FIG. 5 is a perspective view of a second main flow path member of FIG. 3;

FIG. 6 is a perspective view illustrating a state in which the atomic layer deposition apparatus of FIG. 1 performs a process;

FIG. 7 is a cross-sectional view taken along line X1-X1′ of FIG. 6;

FIG. 8 is an enlarged view of area A of FIG. 7;

FIG. 9 is an enlarged view of area B of FIG. 7;

FIG. 10 is an enlarged view of area C of FIG. 7;

FIG. 11 is an enlarged exploded perspective view illustrating a path through which a first gas is distributed through a first gas distribution flow path portion formed in an upper flow path forming member of the atomic layer deposition apparatus of FIG. 1;

FIG. 12 is a plan view of the first gas distribution flow path portion of FIG. 11;

FIG. 13 is a view illustrating a path through which the first gas distributed through the first gas distribution flow path portion of FIG. 11 is distributed again through first gas supply flow path portions formed in the first main flow path member;

FIG. 14 is an enlarged exploded perspective view illustrating a path through which a second gas is distributed through a second gas distribution flow path portion formed in a first lower flow path forming member of the atomic layer deposition apparatus of FIG. 1;

FIG. 15 is a plan view of the second gas distribution flow path portion of FIG. 14;

FIG. 16 is a view illustrating a path through which the second gas distributed through the second gas distribution flow path portion of FIG. 14 is distributed again through second gas supply flow path portions formed in the first main flow path member;

FIG. 17 is a view illustrating a path through which a gas supplied through the first main flow path member moves to the second main flow path member;

FIG. 18 is a view illustrating a path through which the gas supplied through the first main flow path member moves to gas merging flow path portions formed in the upper flow path forming member through gas exhaust flow path portions formed in the second main flow path member;

FIG. 19 is a view illustrating a path through which the gas supplied through the first main flow path member is concentrated by the gas merging flow path portions;

FIG. 20 is a view illustrating a path through which the gas concentrated by the gas merging flow path portions is discharged through an exhaust part;

FIGS. 21 through 29 are views for explaining an embodiment of an atomic layer deposition process using the atomic layer deposition apparatus of FIG. 1; and

FIG. 30 is a structural diagram illustrating the structure of an atomic layer deposition apparatus according to an alternative embodiment.

### DETAILED DESCRIPTION

The invention will now be described more fully hereinafter with reference to the accompanying drawings, in which various embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art. Like reference numerals refer to like elements throughout.

It will also be understood that when a layer is referred to as being “on” another layer or substrate, it can be directly on the other layer or substrate, or intervening layers may also be present. In contrast, when an element is referred to as being “directly on” another element, there are no intervening elements present.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Features of each of various embodiments of the present disclosure may be partially or entirely combined with each other and may technically variously interwork with each other, and respective embodiments may be implemented independently of each other or may be implemented together in association with each other.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the invention will be described in detail with reference to the accompanying drawings.

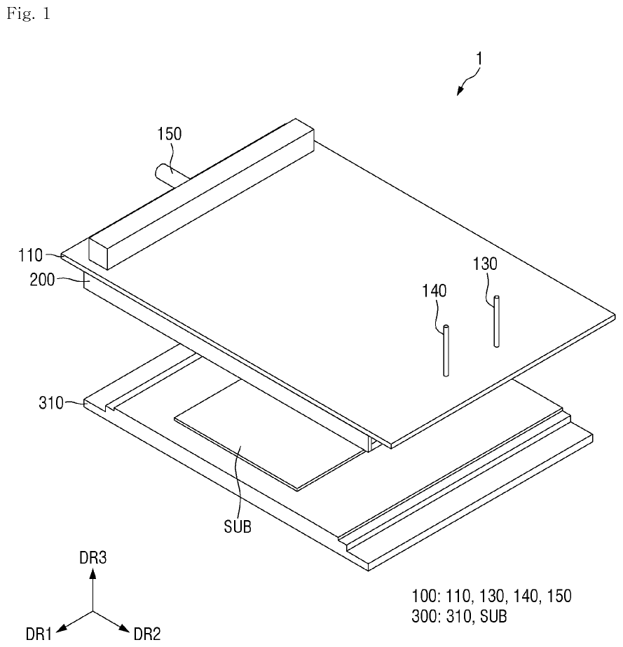

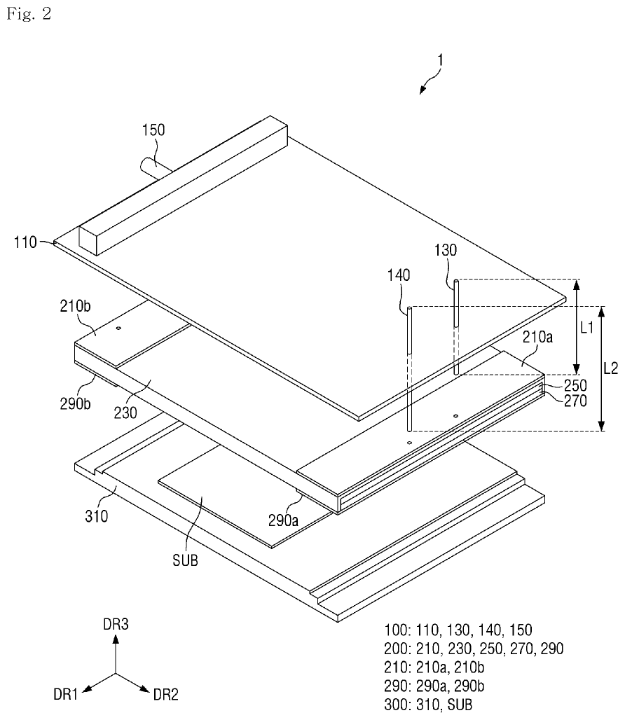

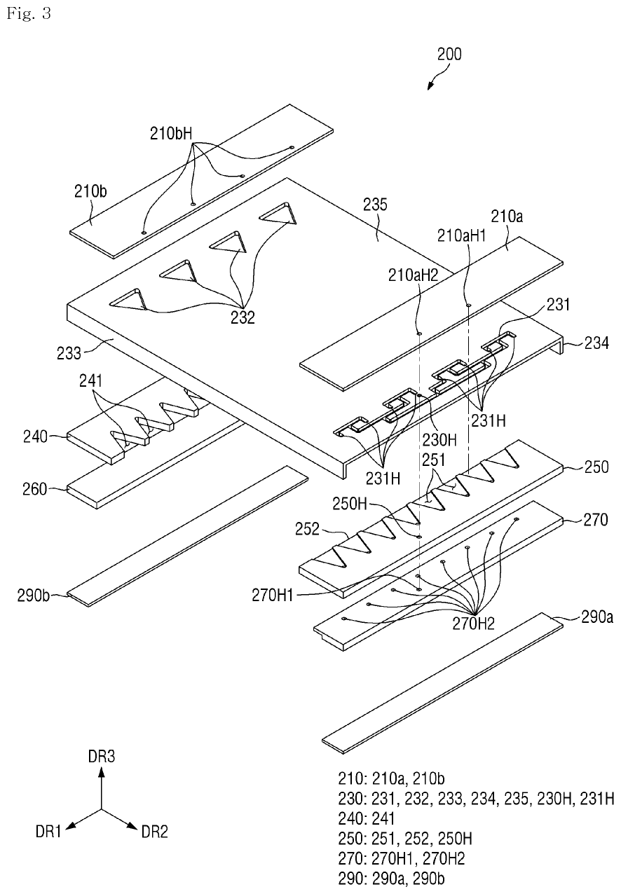

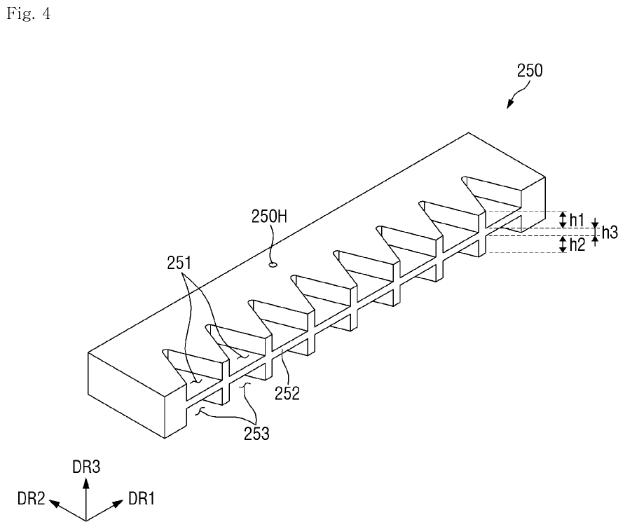

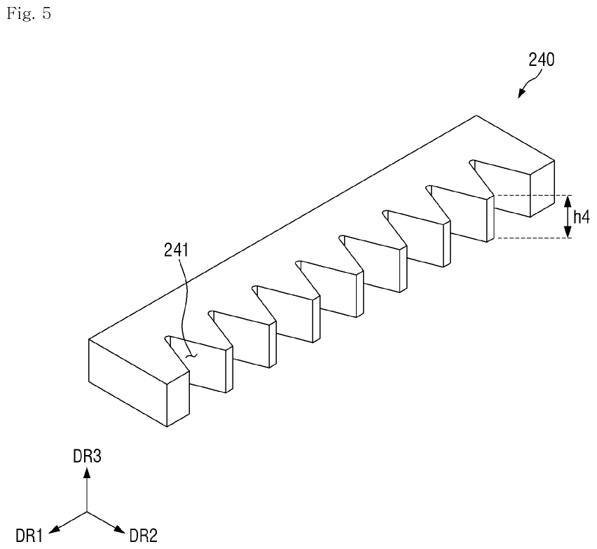

FIG. 1 is a perspective view illustrating an atomic layer deposition apparatus 1 according to an embodiment in a state before performing a process. FIG. 2 is an exploded perspective view of the atomic layer deposition apparatus 1 of FIG. 1. FIG. 3 is an exploded perspective view of a process module 200 of the atomic layer deposition apparatus 1 of FIG. 1. FIG. 4 is a perspective view of a first main flow path member 250 of FIG. 3. FIG. 5 is a perspective view of a second main flow path member 240 of FIG. 3.

In FIG. 1, a first direction DR1, a second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. It may be understood that the first direction DR1 refers to a horizontal direction in the drawing, the second direction DR2 refers to a vertical direction in the drawing, and the third direction DR3 refers to an up-down direction in the drawing, that is, a thickness direction. In the following specification, unless otherwise specified, a “direction” may refer to both directions extending to both sides along the direction. In addition, among both sides to which both “directions” extend, respectively, one side is referred to as “one side in the direction,” and the other side is referred to as “the other side in the direction.” Based on FIG. 1, a direction in which an arrow is directed is referred to as one side, and a direction opposite to the direction is referred to as the other side.

Hereinafter, for ease of description, in referring to surfaces of the atomic layer deposition apparatus 1 or each member constituting the atomic layer deposition apparatus 1, one surface facing one side in the third direction DR3 is referred to as a top surface, and a surface opposite the one surface is referred to as a bottom surface. However, the disclosure is not limited thereto, and the one surface and the other surface of each member may also be referred to as a front surface and a rear surface, respectively, or may be referred to as a first surface and a second surface. In addition, in describing relative positions of the members of the atomic layer deposition apparatus 1, one side in the third direction DR3 may be referred to as an upper side, and the other side in the third direction DR3 may be referred to as a lower side.

Referring to FIGS. 1 through 5, an embodiment of the atomic layer deposition apparatus 1 includes a stage module 300, the process module 200, and a chamber module 100 to inject a gas into a predetermined area of a substrate SUB while anchoring the substrate SUB during a deposition process.

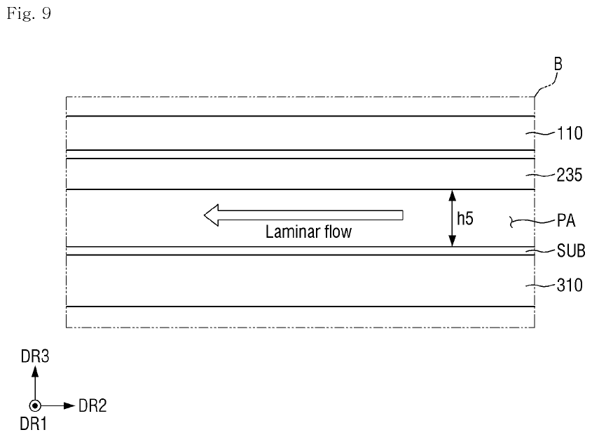

The stage module 300 may provide the substrate SUB and a process area PA (see FIG. 9) on which a process is performed together with the process module 200, as will be described later. The stage module 300 may include a substrate support 310 and the substrate SUB.

The substrate SUB is a target substrate SUB on which a deposition process is performed and may be placed on an area of the substrate support 310.

The substrate support 310 is a component that anchors the substrate SUB and controls or provides a temperature for a deposition process to the substrate SUB. The substrate support 310 may be referred to as a susceptor. The substrate support 310 may move in the third direction DR3. in an embodiment, the substrate support 310 may be driven to be spaced apart from the process module 200 and the chamber module 100 in the third direction DR3 so that the substrate SUB may be placed on the substrate support 310. The substrate support 310 may be driven to be in close contact with the process module 200 in the third direction DR3 so that an atomic layer deposition process to be described later can be performed. This will be described in detail later. While a deposition material is deposited on the substrate SUB in an atomic layer deposition process, the substrate SUB is fixed without being moved.

A portion of the substrate support 310 may be shaped like a flat plate, that is, in a flat plate-like shape, to support the substrate SUB thereon. In addition, both ends of the substrate support 310 in the second direction DR2 may be stepped to be engaged with the structure of the process module 200 as will be described later. This will be described later.

The chamber module 100 may supply or discharge a gas used in a process to the process module 200 and seal an upper portion of the process module 200 to prevent the gas from leaking. The chamber module 100 may include a chamber lid 110, an exhaust part 150, a first gas pipe 130, and a second gas pipe 140.

The chamber lid 110 of the chamber module 100 may define or form a base of the chamber module 100. In some embodiments, the chamber lid 110 may be shaped like a rectangular parallelepiped flat plate, but the disclosure is not limited thereto. In an alternative embodiment, for example, the chamber lid 110 may also be shaped like a circular disc. In FIGS. 1 and 2, an embodiment where the chamber lid 110 is shaped like a rectangular parallelepiped flat plate is shown.

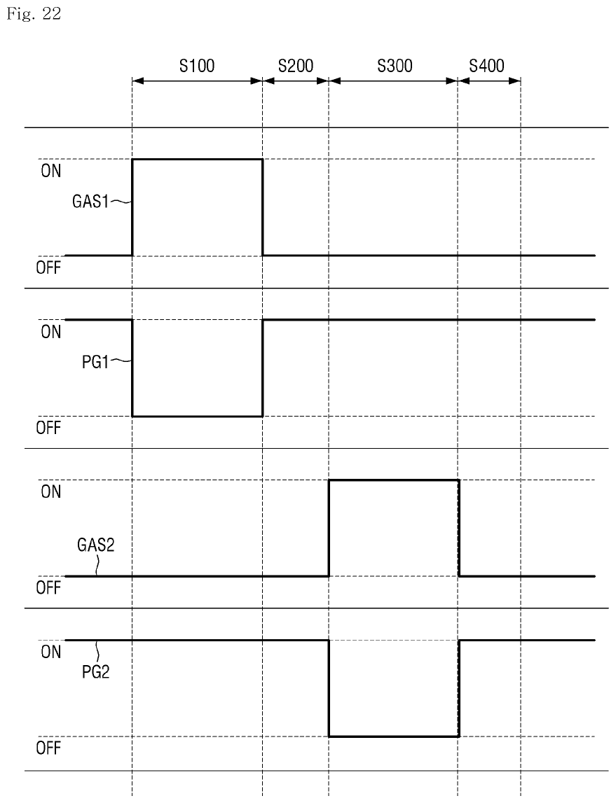

Each of the first gas pipe 130 and the second gas pipe 140 of the chamber module 100 may be disposed or pass through the chamber lid 110 to supply a gas used for a process to the process module 200. In an embodiment, the first gas pipe 130 may supply a first gas GAS1 (see FIG. 22) or a first purge gas PG1 (see FIG. 22) to the process module 200, and the second gas pipe 140 may supply a second gas GAS2 (see FIG. 22) or a second purge gas PG2 (see FIG. 22) to the process module 200. The first gas pipe 130 and the second gas pipe 140 may be spaced apart from each other. A length L1 of the first gas pipe 130 in the third direction DR3 may be greater than a length L2 of the second gas pipe 140 in the third direction DR3. This will be described later.

In an atomic layer deposition process using the atomic layer deposition apparatus 1 according to an embodiment, the first gas GAS1 may be a precursor including, for example, a metal oxide such as trimethylaluminum (TMA), the second gas GAS2 may be a counter reactant including a material such as water (H₂O), hydrogen peroxide (H₂O₂) or ozone (O₃), and the first purge gas PG1 and the second purge gas PG2 may be non-reactive, inert gas including argon (Ar) or the like. A detailed process of the atomic layer deposition process using the first gas GAS1, the second gas GAS2, the first purge gas PG1, and the second purge gas PG2 will be described later. In this specification, the first gas GAS1 may be referred to as a ‘reaction source,’ the second gas GAS2 may be referred to as a ‘reaction gas,’ and the first purge gas PG1 and the second purge gas PG2 may be referred to as ‘purge gases.’

The first gas pipe 130 may be connected to first gas supply flow path portions 251 of the process module 200, and the second gas pipe 140 may be connected to second gas supply flow path portions 253 as will be described later.

The exhaust part 150 of the chamber module 100 may be disposed on the chamber lid 110 to discharge the first gas GAS1, the second gas GAS2, the first purge gas PG1 and the second purge PG2 remaining after being used for reaction. The exhaust part 150 may be connected to gas exhaust flow path portions 241 of the process module 200 as will be described later. The exhaust part 150 is a single pipe and may discharge the first gas GAS1, the second gas GAS2, the first purge gas PG1, and the second purge gas PG2 remaining after being used for reaction.

In an embodiment, the exhaust part 150 and the first and second gas pipes 130 and 140 may be spaced apart to face each other in the second direction DR2. In such an embodiment, the first gas GAS1, the second gas GAS2, the first purge gas PG1, and the second purge gas PG2 used in an atomic layer deposition process to be described later flow in the second direction DR2. This will be described later. In some embodiments, the exhaust part 150 may be disposed at an end of the chamber lid 110 on the other side in the second direction DR2, and the first gas pipe 130 and the second gas pipe 140 may be disposed on one side in the second direction DR2, but the disclosure is not limited thereto.

Although the exhaust part 150, the first gas pipe 130, and the second gas pipe 140 are disposed on the chamber lid 110 in FIGS. 1 and 2, the disclosure is not limited thereto. In an embodiment, for example, the exhaust part 150, the first gas pipe 130, and the second gas pipe 140 may also be spaced apart from the chamber lid 110 and disposed as separate components. For ease of description, the exhaust part 150, the first gas pipe 130, and the second gas pipe 140 will be mainly described below as being disposed on the chamber lid 110.

The process module 200 may deposit a thin film while injecting the first gas GAS1, the second gas GAS2, etc. onto the substrate SUB of the stage module 300 in a time division manner. In an embodiment, as illustrated in FIG. 3, the process module 200 may include upper shielding plates 210, an upper flow path forming member 230, the first main flow path member 250, the second main flow path member 240, a first lower flow path forming member 270, a second lower flow path forming member 260, and lower shielding plates 290.

The upper shielding plates 210 of the process module 200 may form (or define) flow paths by covering a first gas distribution flow path portion 231 and gas merging flow path portions 232 formed (or defined) in the upper flow path forming member 230, as will be described later. Each of the upper shielding plates 210 may be shaped like a flat plate. The upper shielding plates 210 may include a first upper shielding plate 210a disposed on one side in the second direction DR2 and a second upper shielding plate 210b disposed on the other side in the second direction DR2.

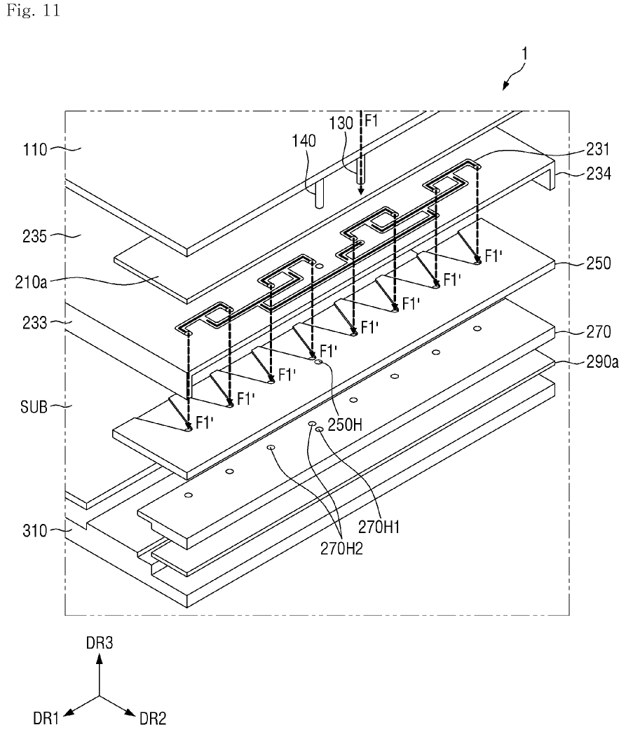

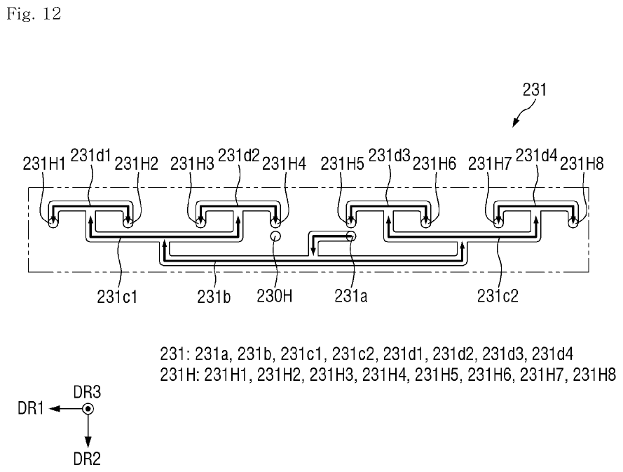

The first upper shielding plate 210a among the upper shielding plates 210 overlaps the first gas distribution flow path portion 231 in the third direction DR3 to define or form a flow path by covering and sealing a top surface of the first gas distribution flow path portion 231. The flow path defined or formed by the first gas distribution flow path portion 231 and the first upper shielding plate 210a may be a path through which the first gas GAS1 is divided into several streams and delivered to the first gas supply flow path portions 251 as will be described later (see FIGS. 11 and 12).

The first upper shielding plate 210a may include a first through-hole 210aH1 and a second through-hole 210aH2 formed through the first upper shielding plate 210a in the third direction DR3, that is, the first through-hole 210aH1 and the second through-hole 210aH2 are defined through the first upper shielding plate 210a in the third direction DR3. The first through-hole 210aH1 is a hole through which the first gas pipe 130 passes or is disposed and may provide a path through which a gas supply portion of the first gas distribution flow path portion 231 and the first gas pipe 130 are connected. The second through-hole 210aH2 may provide a path through which the second gas pipe 140 is disposed or passes through the first upper shielding plate 210a.

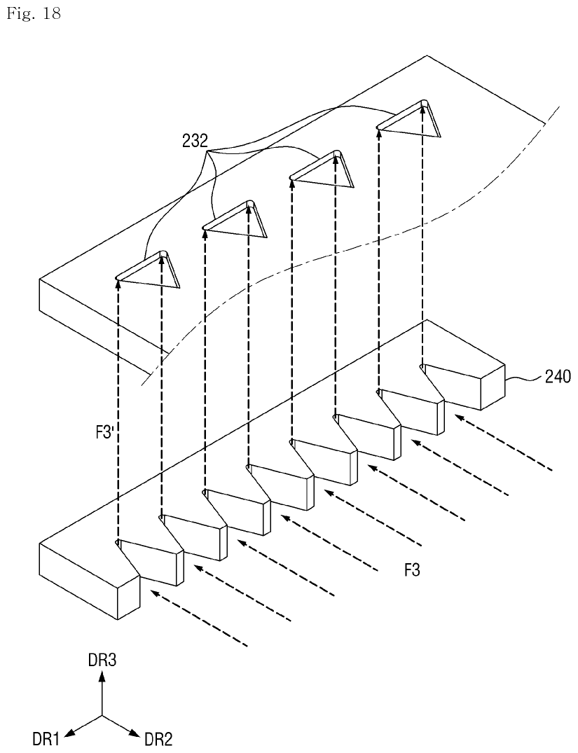

The second upper shielding plate 210b among the upper shielding plates 210 overlaps the gas merging flow path portions 232 in the third direction DR3 to define or form a flow path by covering and sealing top surfaces of the gas merging flow path portions 232. The flow path formed by the gas merging flow path portions 232 and the second upper shielding plate 210b may be a path through which streams of gas exhausted after being used in a process are merged and delivered to the exhaust part 150 as will be described later (see FIGS. 18 through 20).

The second upper shielding plate 210b may include a plurality of exhaust through-holes 210bH formed through the second upper shielding plate 210b in the third direction DR3, that is, plurality of exhaust through-holes 210bH may be defined through the second upper shielding plate 210b in the third direction DR3. As described above, gases merged by the gas merging flow path portions 232 may pass through the exhaust through-holes 210bH and move to the exhaust part 150.

The upper flow path forming member 230 of the process module 200 may define or provide a path through which the first gas GAS1 is distributed and delivered to the first gas supply flow path portions 251 and a path through which gases exhausted after being used in a process are merged and delivered to the exhaust part 150. The upper flow path forming member 230 may include a body portion 235, a first cover portion 233, and a second cover portion 234.

The body portion 235 of the upper flow path forming member 230 is a flat plate that forms a base of the upper flow path forming member 230. The body portion 235 may be a flat plate having a rectangular planar shape when seen in the third direction DR3. The first gas distribution flow path portion 231 and the gas merging flow path portions 232 may be formed in a top surface of the body portion 235, and an upper through-hole 230H and a plurality of first distribution holes 231H may be formed through the body portion 235 in the third direction DR3.

The first gas distribution flow path portion 231 formed in the body portion 235 forms a flow path with the first upper shielding plate 210a as described above to provide a path through which the first gas GAS1 is divided into several streams and distributed to the first gas supply flow path portions 251. The gas merging flow path portions 232 form a flow path with the second upper shielding plate 210b to provide a path through which gases remaining after being used in a process are merged and discharged to the exhaust part 150. The first gas distribution flow path portion 231 and the gas merging flow path portions 232 may be spaced apart from each other in the second direction DR2 on the top surface of the body portion 235. In an embodiment, the first gas distribution flow path portion 231 may be located at an end of the body portion 235 in the second direction DR2, and the gas merging flow path portions 232 may be located at the other end of the body portion 235 in the second direction DR2.

The first gas distribution flow path portion 231 may overlap the first main flow path member 250, the first lower flow path forming member 270, and a first lower shielding plate 290a, which will be described later, in the third direction DR3. The gas merging flow path portions 232 may overlap the second main flow path member 240, the second lower flow path forming member 260, and a second lower shielding plate 290b, which will be described later, in the third direction DR3. The first distribution holes 231H formed in the first gas distribution flow path portion 231 may serve as passages through which the first gas GAS1 divided through the flow path formed by the first gas distribution flow path portion 231 and the first upper shielding plate 210a is delivered to the first gas supply flow path portions 251. The specific shape of the first gas distribution flow path portion 231 and the specific shape of the gas merging flow path portions 232 will be described in detail later.

The upper through-hole 230H defined through the body portion 235 may be a passage through which the second gas pipe 140 passes. The second gas pipe 140 may be connected to the second lower flow path forming member 260, which will be described later, to supply the second gas GAS2 to the second gas supply flow path portions 253.

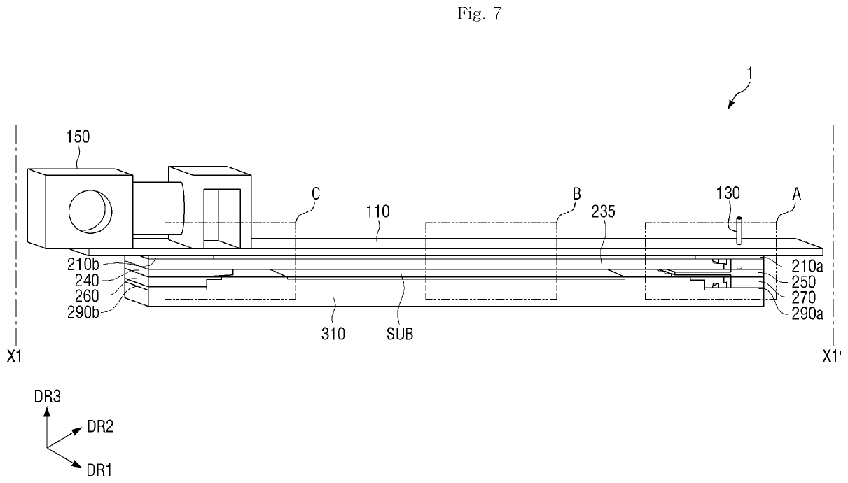

The first main flow path member 250, the second main flow path member 240, the first lower flow path forming member 270, and the second lower flow path forming member 260, which will be described later, may be disposed on a bottom surface of the body portion 235, that is, under the body portion 235. The first main flow path member 250 and the first lower flow path forming member 270 may be spaced apart from the second main flow path member 240 and the second lower flow path forming member 260 to face each other in the second direction DR2. A space between the first main flow path member 250 and the second main flow path member 240 may be defined as the process area PA (see FIGS. 7 and 9) which will be described later.

The first cover portion 233 and the second cover portion 234 may be disposed on side surfaces of the body portion 235. The body portion 235, the first cover portion 233, and the second cover portion 234 may be integrally formed with each other as a single unitary and indivisible part. The first cover portion 233 and the second cover portion 234 may prevent the process area PA, which will be described later, from being exposed to the outside. In an embodiment, the first cover portion 233 may cover side surfaces of the first main flow path member 250, the second main flow path member 240, the first lower flow path forming member 270, and the second lower flow path forming member 260 disposed under the body portion 235 on one side in the first direction DR1. The second cover portion 234 may cover side surfaces of the first main flow path member 250, the second main flow path member 240, the first lower flow path forming member 270, and the second lower flow path forming member 260 disposed under the body portion 235 on the other side in the first direction DR1 (see FIG. 2). Therefore, it is possible to prevent the process area PA from being exposed to the outside, thereby preventing leakage of gases used in a process.

The first main flow path member 250 and the second main flow path member 240 of the process module 200 may directly contact the bottom surface of the body portion 235 of the upper flow path forming member 230. Accordingly, a top surface of the first main flow path member 250 and a top surface of the second main flow path member 240 may be sealed by the bottom surface of the body portion 235. The first main flow path member 250 and the second main flow path member 240 may be spaced apart from each other in the second direction DR2. In an embodiment, the first main flow path member 250 may overlap the first gas distribution flow path portion 231 in the third direction DR3, and the second main flow path member 240 may overlap the gas merging flow path portions 232 in the third direction DR3.

The first main flow path member 250 may supply the first gas GAS1 and the second gas GAS2 respectively supplied from the first gas pipe 130 and the second gas pipe 140 to the process area PA. In an embodiment, as illustrated in FIG. 4, the first main flow path member 250 may include the first gas supply flow path portions 251 for supplying the first gas GAS1 to the process area PA and the second gas supply flow path portions 253 for supplying the second gas GAS2 to the process area PA. The first main flow path member 250 may include a main through-hole 250H through which the second gas pipe 140 passes, and the first gas pipe 130 may not pass through the first main flow path member 250. A path through which the first gas GAS1 moves to the first gas supply flow path portions 251 and a path through which the second gas GAS2 moves to the second gas supply flow path portions 253 will be described later.

A plurality of first gas supply flow path portions 251 may be arranged side by side in the first direction DR1. The number of the first gas supply flow path portions 251 may correspond to the number of the first distribution holes 231H described above. In an embodiment, as shown in FIG. 4, eight first gas supply flow path portions 251 may be provided, but the number of the first gas supply flow path portions 251 is not limited thereto.

Each of the first gas supply flow path portions 251 may be a radial space having a width in the first direction DR1 gradually increasing as being toward the other side in the second direction DR2 based on FIG. 4. In such an embodiment, the first gas supply flow path portions 251 may be shaped like grooves partially cut into the top surface of the first main flow path member 250. As will be described later, the first gas GAS1 divided into several streams by the first gas distribution flow path portion 231 may move to the first gas supply flow path portions 251 and then move to the other side in the second direction DR2 through the first gas supply flow path portions 251 to enter the process area PA. In such an embodiment, as the first gas GAS1 moves to the other side in the second direction DR2, the flow of the first gas GAS1 may be evenly spread by each of the first gas supply flow path portions 251 having the gradually increasing width in the first direction DR1, thereby reducing the flow velocity of the first gas GAS1 supplied to the process area PA. Accordingly, the first gas GAS1 may be induced to be supplied to and flow in the process area PA in a laminar flow pattern. This will be described in detail later.

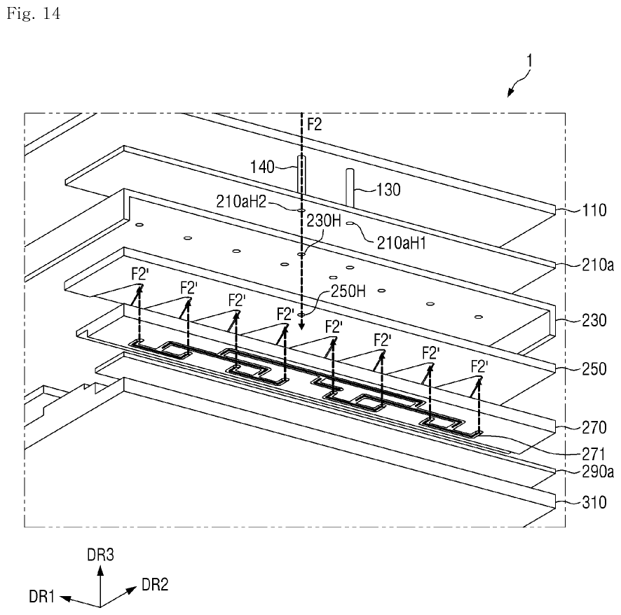

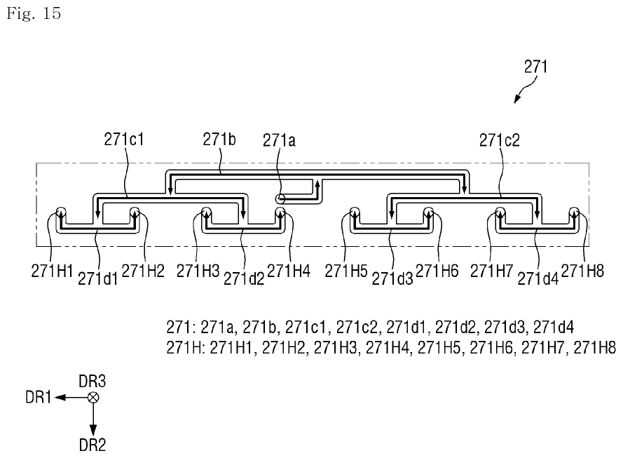

The second gas supply flow path portions 253 may be disposed under the first gas supply flow path portions 251. Like the first gas supply flow path portions 251, a plurality of second gas supply flow path portions 253 may be arranged side by side in the first direction DR1. The number of the second gas supply flow path portions 253 may correspond to the number of second distribution holes 271H (see FIGS. 14 and 15) which will be described later. In an embodiment, as shown in FIG. 4, eight second gas supply flow path portions 253 may be provided, but the number of the second gas supply flow path portions 253 is not limited thereto. In some embodiments, the second gas supply flow path portions 253 may be placed to correspond to the first gas supply flow path portions 251, respectively, but the disclosure is not limited thereto.

Each of the second gas supply flow path portions 253 may be a radial space having a width in the first direction DR1 gradually increasing as being toward the other side in the second direction DR2 based on FIG. 4. In such an embodiment, the second gas supply flow path portions 253 may be shaped like grooves partially cut into a bottom surface of the first main flow path member 250. As will be described later, the second gas GAS2 divided into several streams by a second gas distribution flow path portion 271 (see FIGS. 14 and 15) may move to the second gas supply flow path portions 253 and then move to the other side in the second direction DR2 through the second gas supply flow path portions 253 to enter the process area PA. In such an embodiment, as the second gas GAS2 moves to the other side in the second direction DR2, the flow of the second gas GAS2 may be evenly spread by each of the second gas supply flow path portions 253 having the gradually increasing width in the first direction DR1, thereby reducing the flow velocity of the second gas GAS2 supplied to the process area PA. Accordingly, like the first gas GAS1, the second gas GAS2 may be induced to be supplied to and flow in the process area PA in a laminar flow pattern.

Laminar flow described herein may refer to a form of fluid behavior and a form of fluid flow in which a fluid flows in layers with the layers being hardly mixed. The behavior of a fluid may be classified or determined by the flow velocity, density, flow length, and viscosity of the fluid. Specifically, the behavior of the fluid may be defined by the magnitude of the Reynolds number (Re) according to Equation 1 below.

$$Re = \frac{ρ uL}{μ} . \qquad ( Equation 1 )$$

In Equation 1, ‘Re’ denotes a dimensionless Reynolds number, ‘ρ’ denotes the density of a fluid, ‘u’ denotes the flow velocity of the fluid, ‘L’ denotes the characteristic length of the fluid, and ‘μ’ denotes the viscosity coefficient of the fluid. In general, as the Reynolds number is smaller, a fluid tends to behave as a laminar flow, and as the Reynolds number is larger, the fluid tends to behave as a turbulent flow which is a disordered fluid flow pattern in which the magnitude and direction of the flow velocity at each point change every moment. In other words, as the flow velocity, density, and characteristic length of the fluid are smaller and as the viscosity coefficient of the fluid is larger, the fluid has greater tendency to behave as a laminar flow.

For example, if a fluid passes through a cylindrical pipe, the characteristic length L of the fluid is a diameter of the cylindrical shape. The fluid may behave as a laminar flow when the Reynolds number is about 2100 or less and may behave as a turbulent flow when the Reynolds number exceeds about 4000. The range of the Reynolds number used to determine whether the behavior of the fluid is laminar or turbulent may vary according to the shape of the pipe in which the fluid behaves.

A flow path partitioning portion 252 may be disposed between the first gas supply flow path portions 251 and the second gas supply flow path portions 253. The flow path partitioning portion 252 may separate the supply of the first gas GAS1 and the supply of the second gas GAS2 to prevent them from being mixed. The flow path partitioning portion 252 may define bottom surfaces of the first gas supply flow path portions 251 and top surfaces of the second gas supply flow path portions 253. In other words, a top surface of the flow path partitioning portion 252 may be the bottom surfaces of the first gas supply flow path portions 251, and a bottom surface of the flow path partitioning portion 252 may be the top surfaces of the second gas supply flow path portions 253.

Top surfaces of the first gas supply flow path portions 251 may be covered by the bottom surface of the body portion 235 of the upper flow path forming member 230. Specifically, the top surfaces of the first gas supply flow path portions 251 may be covered by the bottom surface of a portion of the body portion 235 of the upper flow path forming member 230 which overlaps the first gas distribution flow path portion 231. The bottom surfaces of the first gas supply flow path portions 251 may be covered by the flow path partitioning portion 252. Accordingly, the first gas supply flow path portions 251 may form a first gas supply flow path through which the first gas GAS1 is supplied to the process area PA.

In such an embodiment, the top surfaces of the second gas supply flow path portions 253 are covered by the flow path partitioning portion 252, and bottom surfaces of the second gas supply flow path portions 253 are covered by a top surface of the first lower flow path forming member 270 and an upper surface of the substrate support 310 to be described later. Accordingly, a second gas supply flow path through which the second gas GAS2 is supplied to the process area PA may be formed. This will be described later.

The second main flow path member 240 may form a flow path through which the first gas GAS1 and the second gas GAS2 remaining after being used in a deposition process to be described later are discharged. As illustrated in FIG. 5, the second main flow path member 240 may include a plurality of gas exhaust flow path portions 241 through which the first gas GAS1 and the second gas GAS2 remaining after being used in a deposition process are discharged. In an embodiment, as shown in FIG. 5, eight gas exhaust flow path portions 241 may be provided, but the number of the gas exhaust flow path portions 241 is not limited thereto.

Each of the gas exhaust flow path portions 241 may be a radial space having a width in the first direction DR1 gradually increasing as being toward one side in the second direction DR2 based on FIG. 5, that is, gradually decreasing as being toward the other side in the second direction DR2. The gas exhaust flow path portions 241 may be a portion defined by being cut inward from a side surface of the second main flow path member 240. That is, unlike the shapes of the first gas supply flow path portions 251 and the second gas supply flow path portions 253 of the first main flow path member 250, the gas exhaust flow path portions 241 may be integrally formed through the second main flow path member 240 in the third direction DR3 without a partitioning portion.

Top surfaces of the gas exhaust flow path portions 241 may be covered by the bottom surface of the body portion 235 of the upper flow path forming member 230. In an embodiment, the top surfaces of the gas exhaust flow path portions 241 may be covered by the bottom surface of a portion of the body portion 235 of the upper flow path forming member 230 which overlaps the gas merging flow path portions 232. Bottom surfaces of the gas exhaust flow path portions 241 may be covered by a top surface of the second lower flow path forming member 260 and the top surface of the substrate support 310 which will be described later. Accordingly, the gas exhaust flow path portions 241 may form a gas exhaust flow path through which a gas remaining after being used in a process is discharged. This will be described later.

The gas supplied from the first gas supply flow path portions 251 and the second gas supply flow path portions 253 may move to the exhaust part 150 while its streams are merged as they pass through the process area PA and the gas exhaust flow path. That is, the streams into which the gas has been separated may be merged again while passing through the gas exhaust flow path portions 241. This will be described later.

A width of the first main flow path member 250 in the third direction DR3 (hereinafter, referred to as a ‘thickness’) and a width of the second main flow path member 240 in the third direction DR3 (hereinafter, referred to as a ‘thickness’) may be substantially the same as each other. This may be because a thickness of the process area PA is defined as the thickness of the first main flow path member 250 and the thickness of the second main flow path member 240. The thickness of the first main flow path member 250 may be defined as the sum of a thickness h1 of the first gas supply flow path portions 251, a thickness h2 of the second gas supply flow path portions 253, and a thickness h3 of the flow path partitioning portion 252. In addition, the thickness of the second main flow path member 240 may be defined as a thickness h4 of the gas exhaust flow path portions 241. That is, the thickness h4 of the gas exhaust flow path portions 241 may be substantially the same as the sum of the thickness h1 of the first gas supply flow path portions 251, the thickness h2 of the second gas supply flow path portions 253, and the thickness h3 of the flow path partitioning portion 252.

The first lower flow path forming member 270 and the second lower flow path forming member 260 of the process module 200 may be disposed under the first main flow path member 250 and the second main flow path member 240, respectively.

The first lower flow path forming member 270 may provide a path through which the second gas GAS2 is distributed and moved to the second gas supply flow path portions 253. As illustrated in FIG. 3, the first lower flow path forming member 270 may include a second gas (GAS2) supply hole 270H1 into which the second gas pipe 140 is inserted and a plurality of second distribution holes 270H2 through which the second gas GAS2 are distributed and moved to the second gas supply flow path portions 253. This will be described in detail later with reference to FIGS. 14 through 16.

The second lower flow path forming member 260 may form the gas exhaust flow path by covering a bottom surface of the second main flow path member 240. The second lower flow path forming member 260 may not have a hole, that is, no hole is defined through the second lower flow path forming member 260, to prevent gases remaining after being used for reaction from leaking to portions other than the gas exhaust flow path.

A width of the first lower flow path forming member 270 in the second direction DR2 may be smaller than the width of the first main flow path member 250 in the second direction DR2, and a width of the second lower flow path forming member 260 in the second direction DR2 may be smaller than the width of the second main flow path member 240 in the second direction DR2. Accordingly, the first lower flow path forming member 270 may not completely cover the bottom surfaces of the second gas supply flow path portions 253 of the first main flow path member 250, thus exposing portions of the bottom surfaces of the second gas supply flow path portions 253. The second lower flow path forming member 260 may not completely cover the bottom surfaces of the gas exhaust flow path portions 241 of the second main flow path member 240, thus exposing portions of the bottom surfaces of the gas exhaust flow path portions 241. The exposed portions of the bottom surfaces of the second gas supply flow path portions 253 and the exposed portions of the bottom surfaces of the gas exhaust flow path portions 241 may be covered by the top surface of the substrate support 310 due to a loading behavior of the substrate support 310 to be described later.

The lower shielding plates 290 of the process module 200 may include the first lower shielding plate 290a disposed under the first lower flow path forming member 270 and the second lower shielding plate 290b disposed under the second lower flow path forming member 260.

The first lower shielding plate 290a may form a second gas distribution flow path by covering a bottom surface of the second gas distribution flow path portion 271 formed in a bottom surface of the first lower flow path forming member 270 (see FIG. 14). The second gas pipe 140 may pass through the second through-hole 210aH2 of the first upper shielding plate 210a, the upper through-hole 230H of the upper flow path forming member 230 and the main through-hole 250H of the first main flow path member 250 and may be connected to the second supply holes 270H2 of the first lower flow path forming member 270 to supply the second gas GAS2 to the second gas distribution flow path portion 271 of the first lower flow path forming member 270. This will be described later.

The second lower shielding plate 290b may be disposed under the second lower flow path forming member 260 to directly contact the substrate support 310. However, in some embodiments, the second lower shielding plate 290b may be formed integrally with the second lower flow path forming member 260.

In an embodiment, as described above, the first gas GAS1 and the second gas GAS2 may be supplied to the process area PA in a laminar flow pattern. Thus, the processability of the atomic layer deposition apparatus 1 may be improved. A structure in which the substrate support 310 is loaded and brought into direct contact with a bottom surface of the process module 200 to form the second gas supply flow path and the gas exhaust flow path and perform a process will now be described.

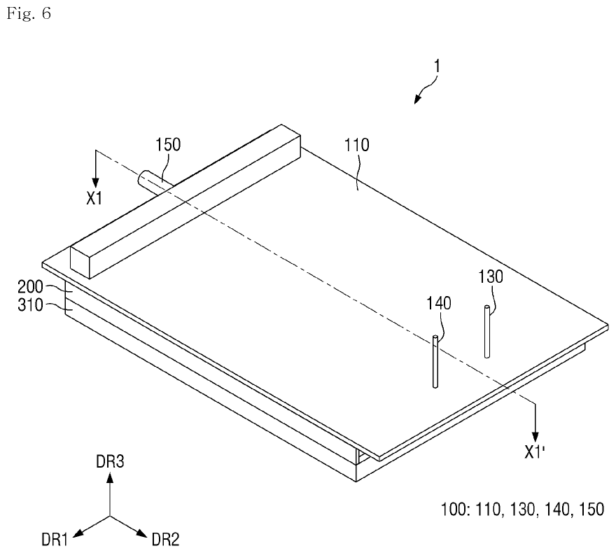

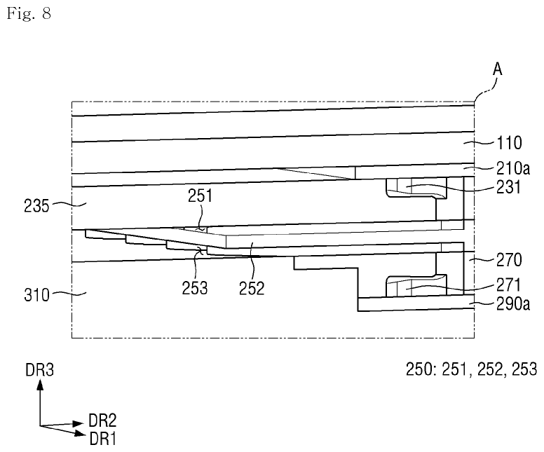

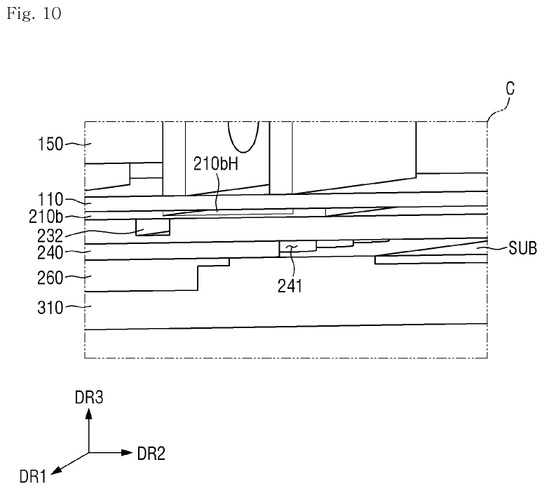

FIG. 6 is a perspective view illustrating a state in which the atomic layer deposition apparatus 1 of FIG. 1 performs a process. FIG. 7 is a cross-sectional view taken along line X1-X1′ of FIG. 6. FIG. 8 is an enlarged view of area A of FIG. 7. FIG. 9 is an enlarged view of area B of FIG. 7. FIG. 10 is an enlarged view of area C of FIG. 7.

Referring to FIGS. 6 through 10, in the atomic layer deposition apparatus 1 according to an embodiment, the substrate support 310 is loaded, that is, moved to one side in the third direction DR3 to come into contact with the process module 200, thereby forming a flow path through which gases used in a process pass.

In an embodiment, as illustrated in FIG. 8, the top surfaces of the first gas supply flow path portions 251 may be covered by the bottom surface of the body portion 235 of the upper flow path forming member 230, and the bottom surfaces of the first gas supply flow path portions 251 may be covered by the flow path partitioning portion 252. Therefore, the first gas supply flow path through which the first gas GAS1 is supplied to the process area PA may be formed. The top surfaces of the second gas supply flow path portions 253 may be covered by the flow path partitioning portion 252, and the bottom surfaces of the second gas supply flow path portions 253 may be covered by the top surface of the first lower flow path forming member 270 and the top surface of the substrate support 310. Therefore, the second gas supply flow path through which the second gas GAS2 is supplied to the process area PA may be formed.

In such an embodiment, a step having a shape corresponding to the shapes of the first lower flow path forming member 270 and the first lower shielding plate 290a may be formed on one side of the substrate support 310 in the second direction DR2. Therefore, the substrate support 310 may move to one side in the third direction DR3 to be engaged with the first lower flow path forming member 270 and the first lower shielding plate 290a.

As described above, in an atomic layer deposition process using the atomic layer deposition apparatus 1 according to an embodiment, the first gas GAS1 may be a precursor including, for example, a metal oxide such as trimethylaluminum (TMA), the second gas GAS2 may be a counter reactant including a material such as water (H₂O), hydrogen peroxide (H₂O₂) or ozone (O₃), and the first purge gas PG1 and the second purge gas PG2 may be non-reactive inert gas including argon (Ar) or the like. in an embodiment where the second gas GAS2 is a counter reactant, the second gas GAS2 includes a gas having a lower molecular weight than the first gas GAS1 which is a precursor. Therefore, the second gas GAS2 having a relatively low molecular weight may easily flow without being trapped in a gap that may be formed because the bottom surfaces of the second gas supply flow path portions 253 are covered by the top surface of the first lower flow path forming member 270 and the top surface of the substrate support 310.

In an embodiment, as illustrated in FIG. 10, the top surfaces of the gas exhaust flow path portions 241 may be covered by the bottom surface of the body portion 235 of the upper flow path forming member 230, and the bottom surfaces of the gas exhaust flow path portions 241 may be covered by the top surface of the second lower flow path forming member 260 and the top surface of the substrate support 310. Therefore, the gas exhaust flow path through which a gas remaining after being used in a process can be discharged may be formed.

In this case, a step having a shape corresponding to the shapes of the second lower flow path forming member 260 and the second lower shielding plate 290b may be formed on the other side of the substrate support 310 in the second direction DR2. Therefore, the substrate support 310 may move to one side in the third direction DR3 to be engaged with the second lower flow path forming member 260 and the second lower shielding plate 290b.

The stage module 300 and the body portion 235 of the upper flow path forming member 230 may be spaced apart from each other in the third direction DR3 with the first main flow path member 250 and the second main flow path member 240 interposed between them. A space between the stage module 300 and the body portion 235 or a space between the first main flow path member 250 and the second main flow path member 240 may be defined as the process area PA in which an atomic layer process is performed as illustrated in FIG. 9.

A width of the process area PA in the third direction DR3 (hereinafter, referred to as a ‘thickness’) may be a distance between the stage module 300 and the body portion 235 of the upper flow path forming member 230 in the third direction DR3. Since the stage module 300 and the body portion 235 of the upper flow path forming member 230 are spaced apart by the thickness of the first main flow path member 250 or the thickness h4 of the second main flow path member 240, a thickness h5 of the process area PA may be substantially the same as the thickness h4 of the second main flow path member 240 described above and may be substantially the same as the thickness of the first main flow path member 250, that is, the sum of the thickness h1 of the first gas supply flow path portions 251, the thickness h2 of the second gas supply flow path portions 253, and the thickness h3 of the flow path partitioning portion 252.

The thickness h5 of the process area PA may correspond to the characteristic length in the Reynolds number (Re) of Equation 1 described above. Therefore, the process area PA is desired to have a relatively small thickness h5 for the first gas GAS1 and the second gas GAS2 to move in a laminar flow pattern on the substrate SUB. In some embodiments, the thickness h5 of the process area PA may be in a range of, but not limited to, about 2 millimeters (mm) to about 5 mm.

The process area PA may be an area which is disposed on a top surface of the substrate SUB and in which the first gas GAS1 and the second gas GAS2 may perform an atomic layer deposition process on the substrate SUB. In such an embodiment, the first gas GAS1 and the second gas GAS2 may perform an atomic layer deposition process on the substrate SUB while moving to the other side in the second direction DR2 in a laminar flow pattern on the top surface of the substrate SUB. A path through which the first gas GAS1 is supplied to the process area PA will now be described.

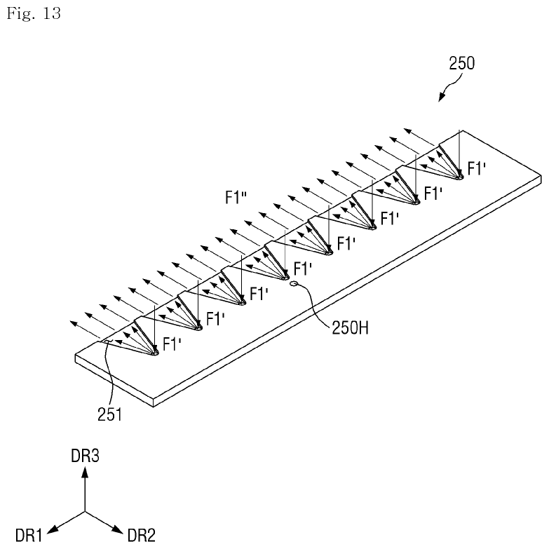

FIG. 11 is an enlarged exploded perspective view illustrating a path through which the first gas GAS1 is distributed through the first gas distribution flow path portion 231 formed in the upper flow path forming member 230 of the atomic layer deposition apparatus 1 of FIG. 1. FIG. 12 is a plan view of the first gas distribution flow path portion 231 of FIG. 11. FIG. 13 is a view illustrating a path through which the first gas GAS1 distributed through the first gas distribution flow path portion 231 of FIG. 11 is distributed again through the first gas supply flow path portions 251 formed in the first main flow path member 250.

Referring to FIGS. 11 through 13, in the atomic layer deposition apparatus 1 according to an embodiment, a fluid flow F1 of the first gas GAS1 supplied to the first gas distribution flow path portion 231 through the first gas pipe 130 may be divided into a plurality of fluid flows F1′ as the fluid flow F1 of the first gas GAS1 passes through the first gas distribution flow path portion 231, and the fluid flows F1′ of the first gas GAS1 may be supplied to the first gas supply flow path portions 251, respectively. The fluid flows F1′ of the first gas GAS1 distributed through the first gas distribution flow path portion 231 may be divided again into a plurality of fluid flows F1″ through the first gas supply flow path portions 251 and may be supplied to the process area PA.

First, the first gas pipe 130 may pass through the first upper shielding plate 210a to supply the first gas GAS1 to the first gas distribution flow path portion 231 formed in the upper flow path forming member 230. The first gas distribution flow path portion 231 may be defined or formed by a groove cut to a predetermined thickness in the top surface of the body portion 235 of the upper flow path forming member 230. As illustrated in FIG. 12, the first gas distribution flow path portion 231 may include a supply portion 231a to which the first gas GAS1 is supplied, a plurality of distribution portions 231b, 231c1, 231c2, 231d1, 231d2, 231d3 and 231d4 for distributing the fluid flow F1 of the first gas GAS1, and a plurality of first distribution holes 231H for transferring the distributed first gas GAS1 to the first gas supply flow path portions 251. In FIG. 12, the distribution portions 231b, 231c1, 231c2, 231d1, 231d2, 231d3 and 231d4 are illustrated as grooves extending in the first direction DR1, and the first distribution holes 231H are illustrated as holes defined through the upper flow path forming member 230 in the third direction DR3.

The distribution portions 231b, 231c1, 231c2, 231d1, 231d2, 231d3 and 231d4 may include a first distribution portion 231b, a first second distribution portion 231c1, a second second distribution portion 231c2, a first third distribution portion 231d1, a second third distribution portion 231d2, a third third distribution portion 231d3, and a fourth third distribution portion 231d4 spaced apart from each other in the second direction DR2. In an embodiment, the first gas GAS1 may be supplied from the first gas pipe 130 to the supply portion 231a and may be distributed into two streams by the first distribution portion 231b along a path extending from the supply portion 231a. The first gas GAS1 may be divided again into two streams by the first second distribution portion 231c1 on one side of the first distribution portion 231b in the first direction DR1 and may be distributed again into two streams by the second second distribution portion 231c2 on the other side of the first distribution portion 231b in the first direction DR1. The first gas GAS1 may be divided again into two streams by the first third distribution portion 231d1 on one side of the first second distribution portion 231c1 in the first direction DR1, by the second third distribution portion 231d2 on the other side of the first second distribution portion 231c1 in the first direction DR1, by the third third distribution portion 231d3 on one side of the second second distribution portion 231c2 in the first direction DR1, and by the fourth third distribution portion 231d4 on the other side of the second second distribution portion 231c2 in the first direction DR1. In such an embodiment, the first gas GAS1 may be divided into eight streams by the first gas distribution flow path portion 231. Accordingly, a first first distribution hole 231H1 may be formed on one side of the first third distribution portion 231d1 in the first direction DR1, a second first distribution hole 231H2 may be formed on the other side of the first third distribution portion 231d1 in the first direction DR1, a third first distribution hole 231H3 may be formed on one side of the second third distribution portion 231d2 in the first direction DR1, a fourth first distribution hole 231H4 may be formed on the other side of the second third distribution portion 231d2 in the first direction DR1, a fifth first distribution hole 231H5 may be formed on one side of the third third distribution portion 231d3 in the first direction DR1, a sixth first distribution hole 231H6 may be formed on the other side of the third third distribution portion 231d3 in the first direction DR1, a seventh first distribution hole 231H7 may be formed on one side of the fourth third distribution portion 231d4 in the first direction DR1, and a eighth first distribution hole 231H8 may be formed on the other side of the fourth third distribution portion 231d4 in the first direction DR1. The first first distribution hole 231H1, the second first distribution hole 231H2, the third first distribution hole 231H3, the fourth first distribution hole 231H4, the fifth first distribution hole 231H5, the sixth first distribution hole 231H6, the seventh first distribution hole 231H7, and the eighth first distribution hole 231H8 may respectively transfer the first gas GAS1 to corresponding first gas supply flow path portions 251 as illustrated in FIG. 13.

In an embodiment, as described above, the first gas supply flow path portions 251 may become wider as being toward the other side in the second direction DR2. Accordingly, the first gas GAS1 may spread along the shape of the first gas supply flow path portions 251 and may be distributed again into several streams.

In such an embodiment, the fluid flow F1 of the first gas GAS1 may be distributed into several streams by the first gas distribution flow path portion 231 and the first gas supply flow path portions 251 to lower the flow velocity. Since the first gas GAS1 is moved and distributed by the first gas distribution flow path portion 231 in the first direction DR1 or the second direction DR2, not in the third direction DR3, the thickness h5 of the process area PA may be reduced or minimized. Therefore, the first gas GAS1 can easily flow in a laminar flow pattern in the process area PA.

A path through which the second gas GAS2 is supplied to the process area PA will now be described.

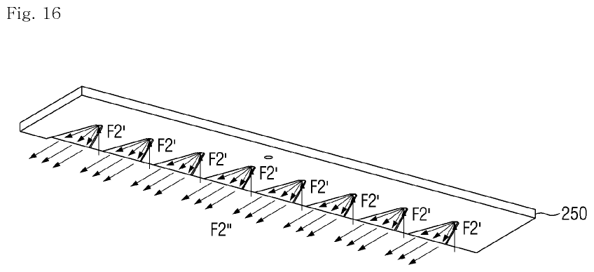

FIG. 14 is an enlarged exploded perspective view illustrating a path through which the second gas GAS2 is distributed through the second gas distribution flow path portion 271 formed in the first lower flow path forming member 270 of the atomic layer deposition apparatus 1 of FIG. 1. FIG. 15 is a plan view of the second gas distribution flow path portion 271 of FIG. 14. FIG. 16 is a view illustrating a path through which the second gas GAS2 distributed through the second gas distribution flow path portion 271 of FIG. 14 is distributed again through the second gas supply flow path portions 253 formed in the first main flow path member 250.

Referring to FIGS. 14 through 16, in the atomic layer deposition apparatus 1 according to an embodiment, a fluid flow F2 of the second gas GAS2 supplied to the second gas distribution flow path portion 271 through the second gas pipe 140 may be divided into a plurality of fluid flows F2′ as the fluid flow F2 of the second gas GAS2 passes through the second gas distribution flow path portion 271, and the fluid flows F2′ of the second gas GAS2 may be supplied to the second gas supply flow path portions 253, respectively. The fluid flows F2′ of the second gas GAS2 distributed through the second gas distribution flow path portion 271 may be divided again into a plurality of fluid flows F2″ through the second gas supply flow path portions 253 and may be supplied to the process area PA.

First, the second gas pipe 140 may pass through the first upper shielding plate 210a, the upper flow path forming member 230, and the first main flow path member 250 to supply the second gas GAS2 to the second gas distribution flow path portion 271 formed in the first lower flow path forming member 270. The second gas distribution flow path portion 271 may be defined or formed by a groove cut to a predetermined thickness in the bottom surface of the first lower flow path forming member 270. As illustrated in FIG. 15, the second gas distribution flow path portion 271 may include a supply portion 271a to which the second gas GAS2 is supplied, a plurality of distribution portions 271b, 271c1, 271c2, 271d1, 271d2, 271d3 and 271d4 for distributing the fluid flow F2 of the second gas GAS2, and a plurality of second distribution holes 271H for transferring the distributed second gas GAS2 to the second gas supply flow path portions 253. In FIG. 15, the distribution portions 271b, 271c1, 271c2, 271d1, 271d2, 271d3 and 271d4 are illustrated as grooves extending in the first direction DR1, and the second distribution holes 271H are illustrated as holes passing through the first lower flow path forming member 270 in the third direction DR3.

The distribution portions 271b, 271c1, 271c2, 271d1, 271d2, 271d3 and 271d4 may include a first distribution portion 271b, a first second distribution portion 271c1, a second second distribution portion 271c2, a first third distribution portion 271d1, a second third distribution portion 271d2, a third third distribution portion 271d3, and a fourth third distribution portion 271d4 spaced apart from each other in the second direction DR2. In such an embodiment, the second gas GAS2 may be supplied from the second gas pipe 140 to the supply portion 271a and may be distributed into two streams by the first distribution portion 271b along a path extending from the supply portion 271a. The second gas GAS2 may be divided again into two streams by the first second distribution portion 271c1 on one side of the first distribution portion 271b in the first direction DR1 and may be distributed again into two streams by the second second distribution portion 271c2 on the other side of the first distribution portion 271b in the first direction DR1. The second gas GAS2 may be divided again into two streams by the first third distribution portion 271d1 on one side of the first second distribution portion 271c1 in the first direction DR1, by the second third distribution portion 271d2 on the other side of the first second distribution portion 271c1 in the first direction DR1, by the third third distribution portion 271d3 on one side of the second second distribution portion 271c2 in the first direction DR1, and by the fourth third distribution portion 271d4 on the other side of the second second distribution portion 271c2 in the first direction DR1. In such an embodiment, the second gas GAS2 may be divided into eight streams by the second gas distribution flow path portion 271. Accordingly, a first second distribution hole 271H1 may be formed on one side of the first third distribution portion 271d1 in the first direction DR1, a second second distribution hole 271H2 may be formed on the other side of the first third distribution portion 271d1 in the first direction DR1, a third second distribution hole 271H3 may be formed on one side of the second third distribution portion 271d2 in the first direction DR1, a fourth second distribution hole 271H4 may be formed on the other side of the second third distribution portion 271d2 in the first direction DR1, a fifth second distribution hole 271H5 may be formed on one side of the third third distribution portion 271d3 in the first direction DR1, a sixth second distribution hole 271H6 may be formed on the other side of the third third distribution portion 271d3 in the first direction DR1, a seventh second distribution hole 271H7 may be formed on one side of the fourth third distribution portion 271d4 in the first direction DR1, and a eighth second distribution hole 271H8 may be formed on the other side of the fourth third distribution portion 271d4 in the first direction DR1. The first second distribution hole 271H1, the second second distribution hole 271H2, the third second distribution hole 271H3, the fourth second distribution hole 271H4, the fifth second distribution hole 271H5, the sixth second distribution hole 271H6, the seventh second distribution hole 271H7, and the eighth second distribution hole 271H8 may respectively transfer the second gas GAS2 to corresponding second gas supply flow path portions 253 as illustrated in FIG. 16.

In an embodiment, as described above, the second gas supply flow path portions 253 may become wider toward the other side in the second direction DR2. Accordingly, the second gas GAS2 may spread along the shape of the second gas supply flow path portions 253 and may be distributed again into several streams.

In such an embodiment, the fluid flow F2 of the second gas GAS2 may be distributed into several streams by the second gas distribution flow path portion 271 and the second gas supply flow path portions 253 to lower the flow velocity. Since the second gas GAS2 is moved and distributed by the second gas distribution flow path portion 271 in the first direction DR1 or the second direction DR2, not in the third direction DR3, the thickness h5 of the process area PA may be reduced or minimized. Therefore, the second gas GAS2 can easily flow in a laminar flow pattern in the process area PA.

A process of exhausting gases remaining after a deposition process is performed will now be described.

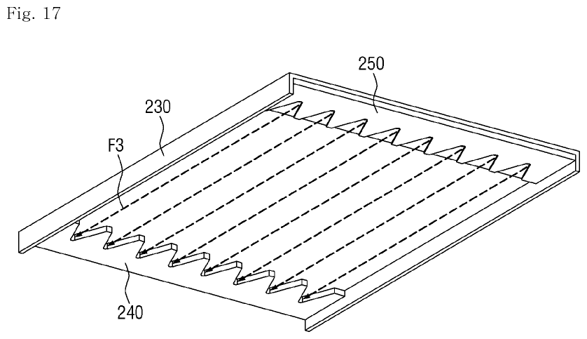

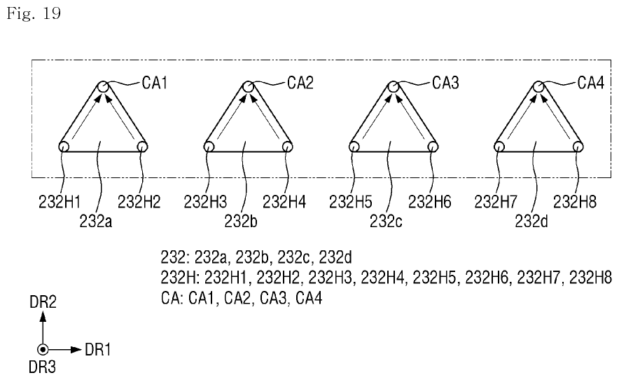

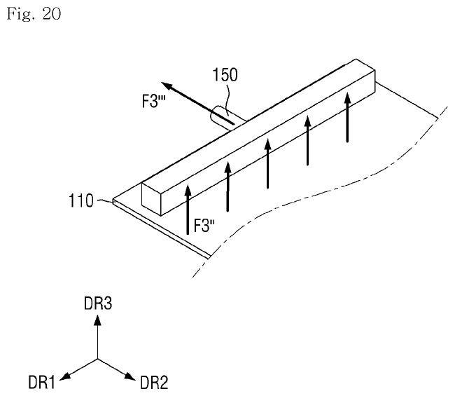

FIG. 17 is a view illustrating a path through which a gas supplied through the first main flow path member 250 moves to the second main flow path member 240. FIG. 18 is a view illustrating a path through which the gas supplied through the first main flow path member 250 moves to the gas merging flow path portions 232 formed in the upper flow path forming member 230 through the gas exhaust flow path portions 241 formed in the second main flow path member 240. FIG. 19 is a view illustrating a path through which the gas supplied through the first main flow path member 250 is concentrated by the gas merging flow path portions 232. FIG. 20 is a view illustrating a path through which the gas concentrated by the gas merging flow path portions 232 is discharged through the exhaust part 150.

Referring to FIGS. 17 through 20, in the atomic layer deposition apparatus 1 according to an embodiment, gases remaining after being used for reaction may be discharged to the outside through the gas exhaust flow path portions 241, the gas merging flow path portions 232, and the exhaust part 150.

In an embodiment, gases supplied through the first main flow path member 250 may flow in a laminar flow pattern and move to the gas exhaust flow path portions 241 of the second main flow path member 240 via the process area PA as illustrated in FIG. 17. A plurality of gas exhaust flow path portions 241 of the second main flow path member 240 may be placed (defined or formed in positions) to correspond to a plurality of first gas supply flow path portions 251 and a plurality of second gas supply flow path portions 253 of the first main flow path member 250, respectively. In such an embodiment, the gas exhaust flow path portions 241 may be placed to face the first gas supply flow path portions 251 or the second gas supply flow path portions 253, respectively.

In an embodiment, as described above, since the gas exhaust flow path portions 241 become narrower along the movement direction of a gas, dispersed fluid flows F3 of the gas supplied to the process area PA through the first gas supply flow path portions 251 or the second gas supply flow path portions 253 may be changed to concentrated fluid flows F3′ as the dispersed fluid flows F3 of the gas passes through the gas exhaust flow path portions 241 and then may flow toward the gas merging flow path portions 232 of the upper flow path forming member 230 as illustrated in FIG. 18. In such an embodiment, the number of the concentrated fluid flows F3′ of the gas may correspond to the number of the gas exhaust flow path portions 241. In an embodiment, where eight gas exhaust flow path portions 241 are provided, the number of the concentrated fluid flows F3′ of the gas may be eight.

The fluid flows F3′ that are concentrated as passing through the gas exhaust flow path portions 241 may be supplied to the gas merging flow path portions 232 through merging holes 232H, and the gases supplied to the gas merging flow path portions 232 may be concentrated again as passing through the gas merging flow path portions 232 and then may be discharged to the exhaust part 150. The gas merging flow path portions 232 may have a triangular shape in a plan view, for example, may have a triangular shape including two merging holes 232H and one concentration portion CA as illustrated in FIG. 19.

A plurality of gas merging flow path portions 232 may be sequentially arranged along the first direction DR1. The number of the gas merging flow path portions 232 may be half the number of the concentrated fluid flows F3′. In an embodiment, for example, when there are eight concentrated fluid flows F3′ of gas, there may be four gas merging flow path portions 232. In such an embodiment, when the gas merging flow path portions 232 are sequentially and respectively referred to as a first gas merging flow path portion 232a, a second gas merging flow path portion 232b, a third gas merging flow path portion 232c, and a fourth gas merging flow path portion 232d along the first direction DR1, the first gas merging flow path portion 232a may include a first merging hole 232H1, a second merging hole 232H2 and a first concentration portion CA1, the second gas merging flow path portion 232b may include a third merging hole 232H3, a fourth merging hole 232H4 and a second concentration portion CA2, the third gas merging flow path portion 232c may include a fifth merging hole 232H5, a sixth merging hole 232H6 and a third concentration portion CA3, and the fourth gas merging flow path portion 232d may include a seventh merging hole 232H7, an eighth merging hole 232H8 and a fourth concentration portion CA4.

Hereinafter, a gas fluid concentration process will be described with reference to the first gas merging flow path portion 232a as an example. In an embodiment, the first merging hole 232H1 and the second merging hole 232H2 are disposed at a base of the first gas merging flow path portion 232a, and the concentrated fluid flows F3′ of a gas pass through the first merging hole 232H1 and the second merging hole 232H2 and then oblique sides of the first gas merging flow path portion 232a to gather at the first concentration portion CA1. Accordingly, the concentrated fluid flows F3′ of the gas supplied to the first gas merging flow path portion 232a may be concentrated into one fluid flow. The gas fluid concentration process performed by the second gas merging flow path portion 232b, the third gas merging flow path portion 232c, and the fourth gas merging flow path portion 232d is substantially the same as the gas fluid concentration process performed by the first gas merging flow path portion 232a, and thus a detailed description thereof will be omitted.

The concentrated fluid flows F3′ of the gas may enter the gas merging flow path portions 232 through corresponding merging holes 232H, respectively, and may be concentrated again by the gas merging flow path portions 232 to move to the exhaust part 150 as fluid flows F3″ as illustrated in FIG. 20. The number of the fluid flow F3″ flowing to the exhaust part 150 may be half (i.e., four) the number of the fluid flows F3′ of the gas concentrated as a result of the gas fluid concentration process described above. The fluid flows F3″ flowing to the exhaust part 150 may be concentrated again into one fluid flow F3′″ by the exhaust part 150 and discharged to the outside.

In such an embodiment, as described above, flows of a gas to be exhausted may be gathered and exhausted as one fluid flow F3″. Therefore, it is possible to reduce an exhaust deviation according to position, that is, an exhaust deviation that may occur because a gas is not exhausted in some portions but is exhausted in some other portions. Accordingly, a used gas may be discharged more effectively.

An atomic layer deposition method using the atomic layer deposition apparatus 1 according to an embodiment will now be described in detail.

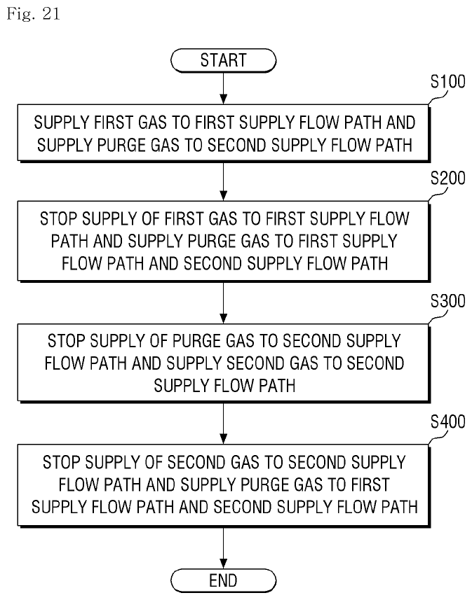

FIGS. 21 through 29 are views for explaining an embodiment of an atomic layer deposition process using the atomic layer deposition apparatus 1 of FIG. 1.

Referring to FIGS. 21 and 22, the atomic layer deposition process using the atomic layer deposition apparatus 1 according to an embodiment is a process of repeating one cycle. The one cycle includes a first operation of supplying a first gas GAS1 to first gas supply flow path portions 251 and supplying a purge gas to second gas supply flow path portions 253 (operation S100), a second operation of stopping the supply of the first gas GAS1 to the first gas supply flow path portions 251 and supplying a purge gas to the first gas supply flow path portions 251 and the second gas supply flow path portions 253 (operation S200), a third operation of stopping the supply of the purge gas to the second gas supply flow path portions 253 and supplying a second gas GAS2 to the second gas supply flow path portions 253 (operation S300), and a fourth operation of stopping the supply of the second gas GAS2 to the second gas supply flow path portions 253 and supplying a purge gas to the first gas supply flow path portions 251 and the second gas supply flow path portions 253 (operation S400).

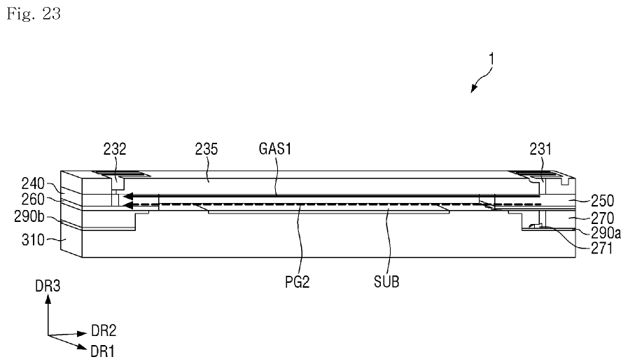

First, referring to FIG. 23 in connection with FIG. 22, in the first operation (operation S100), the first gas GAS1 is supplied to the first gas supply flow path portions 251, and at the same time, a second purge gas PG2 is supplied to the second gas supply flow path portions 253. In this case, a first purge gas PG1 may not be supplied to the first gas supply flow path portions 251, and the second gas GAS2 may not be supplied to the second gas supply flow path portions 253. The first operation (operation S100) may be a process of depositing a reaction source on a substrate SUB in a general atomic layer deposition process. The first gas GAS1 may be deposited on the substrate SUB by moving in a process area PA in a laminar flow pattern toward the other side in the second direction DR2.

Accordingly, since the first gas GAS1 and the second purge gas PG2 are simultaneously supplied in the first operation (operation S100), it is possible to prevent the first gas GAS1 from flowing to the second gas supply flow path portions 253 and help the first gas GAS1 flow to the gas exhaust flow path portions 241. In addition, since the second gas GAS2 is not supplied to the second gas supply flow path portions 253 in the first operation (operation S100), it is possible to prevent the first gas GAS1 from reacting with the second gas GAS2 before the first gas GAS1 is deposited on the substrate SUB.

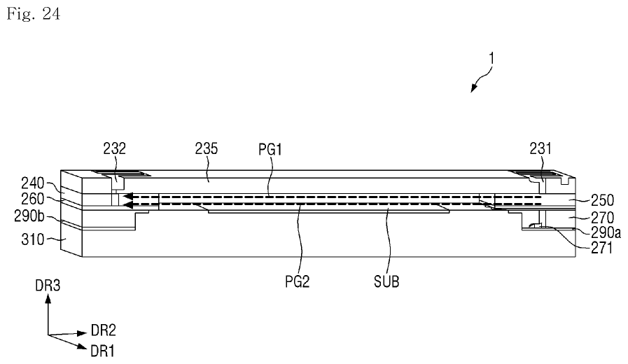

Next, referring to FIG. 24 in connection with FIG. 22, in the second operation (operation S200), the first purge gas PG1 is supplied to the first gas supply flow path portions 251, and at the same time, the second purge gas PG2 is supplied to the second gas supply flow path portions 253. In this case, the first gas GAS1 may not be supplied to the first gas supply flow path portions 251, and the second gas GAS2 may not be supplied to the second gas supply flow path portions 253. The second operation (operation S200) may be a process of purging the reaction source remaining after being used in a process in a general atomic layer deposition process.

Accordingly, since the first purge gas PG1 and the second purge gas PG2 are simultaneously supplied in the second operation (operation S200), it is possible to prevent the first purge gas PG1 from flowing to the second gas supply flow path portions 253 and help the first purge gas PG1 flow to the gas exhaust flow path portions 241 and purge the first gas GAS1.

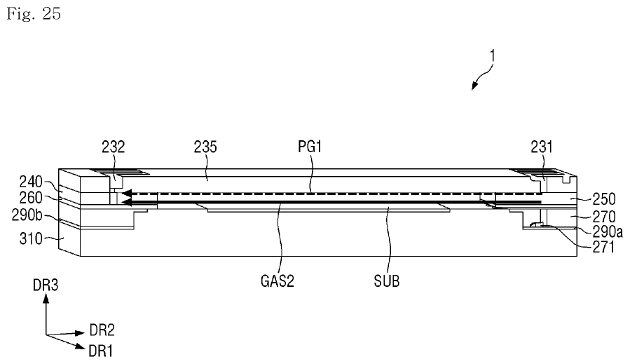

Next, referring to FIG. 25 in connection with FIG. 22, in the third operation (operation S300), the first purge gas PG1 is supplied to the first gas supply flow path portions 251, and at the same time, the second gas GAS2 is supplied to the second gas supply flow path portions 253. In this case, the first gas GAS1 may not be supplied to the first gas supply flow path portions 251, and the second purge gas PG2 may not be supplied to the second gas supply flow path portions 253. The second operation (operation S300) may be a process of forming an atomic layer by reacting a reaction gas with the reaction source deposited on the substrate SUB. The second gas GAS2 may move in the process area PA in a laminar flow pattern toward the other side in the second direction DR2 and form an atomic layer by reacting with the first gas GAS1 deposited on the substrate SUB.

Accordingly, since the first purge gas PG1 and the second gas GAS2 are simultaneously supplied in the third operation (operation S300), it is possible to prevent the second gas GAS2 from flowing to the first gas supply flow path portions 251 and help the second gas GAS2 flow to the gas exhaust flow path portions 241. In addition, since the first gas GAS1 is not supplied to the first gas supply flow path portions 251 in the third operation (operation S300), it is possible to prevent the second gas GAS2 from reacting with the first gas GAS1 before the second gas GAS2 forms an atomic layer by reacting with the first gas GAS1 deposited on the substrate SUB.

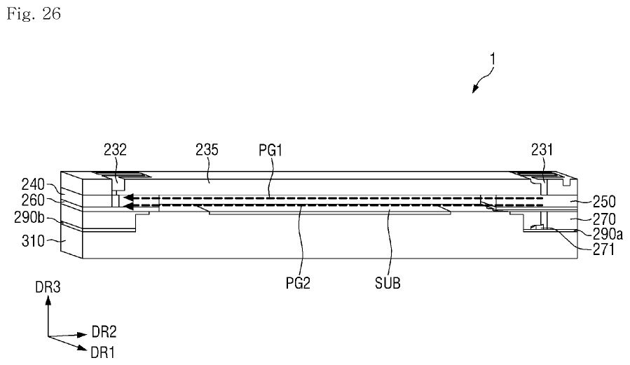

Next, referring to FIG. 26 in connection with FIG. 22, in the fourth operation (operation S400), the first purge gas PG1 is supplied to the first gas supply flow path portions 251, and at the same time, the second purge gas PG2 is supplied to the second gas supply flow path portions 253. In this case, the first gas GAS1 may not be supplied to the first gas supply flow path portions 251, and the second gas GAS2 may not be supplied to the second gas supply flow path portions 253. The fourth operation (operation S200) may be a process of purging the reaction gas remaining after being used in a process in a general atomic layer deposition process.

Accordingly, since the first purge gas PG1 and the second purge gas PG2 are simultaneously supplied in the fourth operation (operation S400), it is possible to prevent the second purge gas PG2 from flowing to the first gas supply flow path portions 251 and help the second purge gas PG2 flow to the gas exhaust flow path portions 241 and purge the second gas GAS2.

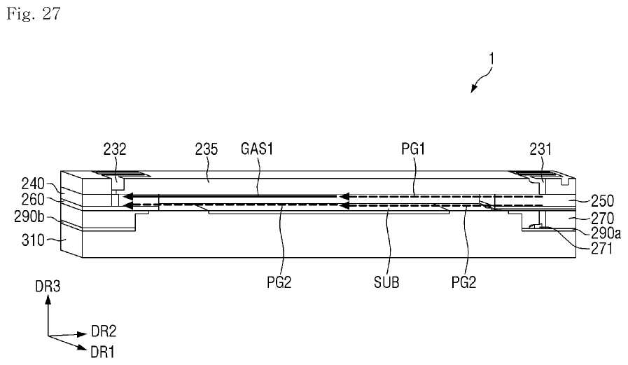

In general, reaction tends to occur effectively when the vapor pressure of a gas increases. Therefore, referring to FIGS. 27 through 29, the vapor pressure of the first gas GAS1 or the second gas GAS2 may be increased to reduce the time spent in each operation (operation S100, S200, S300 or S400), thereby shortening the process time.

In an embodiment, for example, the vapor pressure of the supplied first gas GAS1 may be increased to increase the rate at which the first gas GAS1 is adsorbed onto the surface of the substrate SUB, thereby reducing the time spent for the first operation (operation S100). The vapor pressure of the supplied second gas GAS2 may be increased to increase the rate at which the first gas GAS1 adsorbed onto the substrate SUB reacts with the second gas GAS2, thereby reducing the time spent for the third operation (operation S300).

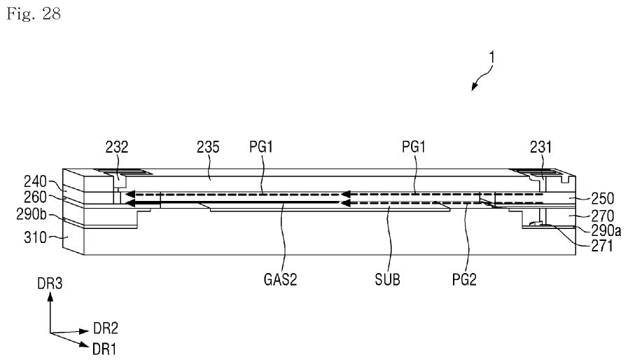

In an embodiment, referring to FIGS. 27 and 28, when the vapor pressure of the first gas GAS1 is increased, even if the first gas GAS1 is not supplied enough to fill the entire process area PA, the first gas GAS1 may be sufficiently supplied in an amount desired for the first gas GAS1 to be adsorbed onto the entire substrate SUB. In addition, since the first gas GAS1 flows in a laminar flow pattern, the first gas GAS1 may pass through the entire process area PA as the first gas GAS1 moves to the other side in the second direction DR2. Therefore, the time spent for the first operation (operation S100) can be reduced. Likewise, when the vapor pressure of the second gas GAS2 is increased, even if the second gas GAS2 is not supplied enough to fill the entire process area PA, the second gas GAS2 may be sufficiently supplied in an amount desired for the second gas GAS2 to form an atomic layer on the entire substrate SUB by reacting with the first gas GAS1 adsorbed onto the substrate SUB. In addition, since the second gas GAS2 flows in a laminar flow pattern, the second gas GAS2 may pass through the entire process area PA as the second gas GAS2 moves to the other side in the second direction DR2. Therefore, the time spent for the third operation (operation S300) can be reduced. In this case, the first gas GAS1 and the first purge gas PG1 may exist simultaneously in the process area PA, or the second gas GAS2 and the second purge gas PG2 may exist simultaneously.

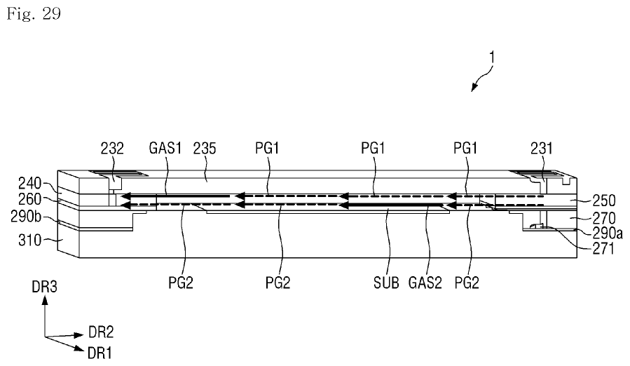

In addition, the time spent for the first operation (operation S100) and the third operation (operation S300) may be further reduced by further increasing the vapor pressure of the supplied first gas GAS1 and the vapor pressure of the supplied second gas GAS2. Therefore, the first gas GAS1, the first purge gas PG1, the second gas GAS2, and the second purge gas PG2 may simultaneously exist in the process area PA as illustrated in FIG. 29.

The atomic layer deposition method described above may improve processability by reducing the time spent for a process.

An alternative embodiment of the atomic layer deposition apparatus 1 will now be described. The same or like elements of an alternative embodiment as those of the embodiments described above are indicated by the same or like reference numerals. In addition, any repetitive detailed description of the same or like elements will be omitted or simplified, and differences will be mainly described.

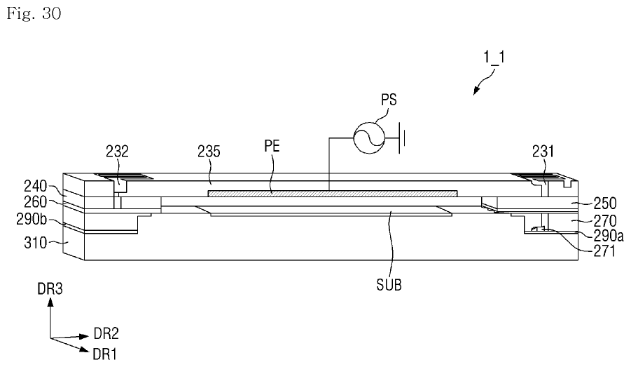

FIG. 30 is a structural diagram illustrating the structure of an atomic layer deposition apparatus 1_1 according to an alternative embodiment.

Referring to FIG. 30, an embodiment of the atomic layer deposition apparatus 1_1 may further include a plasma generator PE to perform a plasma enhanced atomic layer deposition process.

In an embodiment of the atomic layer deposition apparatus 1_1, the plasma generator PE may be mounted on a body portion 235 and placed to face a substrate SUB.

The plasma generator PE may receive power from a power source PS separately installed outside the atomic layer deposition apparatus 1_1 and may emit plasma onto the substrate SUB. Accordingly, in such an embodiment, the atomic layer deposition apparatus 1_1 may perform a plasma enhanced atomic layer deposition process.

In an plasma enhanced atomic layer deposition process, plasma is radiated at the same time as a process of supplying a second gas GAS2, that is, supplying the second gas GAS2 in the third operation (operation S300) described above. Accordingly, the second gas GAS2 may be allowed to more easily react with a first gas GAS1 deposited on the substrate SUB.

In embodiments, as described above, an atomic layer deposition apparatus may be improved in processability.

In embodiments, as described above, an atomic layer deposition method may be improved in processability.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An atomic layer deposition apparatus comprising:
a substrate support which supports a substrate placed thereon;
a process module disposed on the substrate support;
a first gas pipe which supplies a first gas to the process module;
a second gas pipe which supplies a second gas to the process module; and
an exhaust part which discharges the first gas and the second gas supplied to the process module,
wherein the process module comprises:
a first gas supply flow path portion connected to the first gas pipe;
a second gas supply flow path portion disposed under the first gas supply flow path portion and connected to the second gas pipe; and
a gas exhaust flow path portion connected to the exhaust part,
wherein the gas exhaust flow path portion is spaced apart from the first gas supply flow path portion and the second gas supply flow path portion with the substrate interposed therebetween, and
the first gas and the second gas pass through a process area, which is defined as a space between the gas exhaust flow path portion and the first and second gas supply flow path portions, in a laminar flow.

2. The atomic layer deposition apparatus of claim 1, wherein the first gas supply flow path portion and the second gas supply flow path portion are spaced apart from each other with a flow path partitioning portion interposed therebetween.

3. The atomic layer deposition apparatus of claim 2, wherein the first gas supply flow path portion becomes wider along a direction in which the first gas flows.

4. The atomic layer deposition apparatus of claim 3, wherein
the first gas supply flow path portion is provided in plural, and
the first gas supply flow path portions are spaced apart from each other,
wherein the process module further comprises a first gas distribution flow path portion disposed on and connected to the first gas supply flow path portions, wherein the first gas distribution flow path portion divides the first gas into a plurality of flows, and supplies the plurality of flows of the first gas to the first gas supply flow path portions, respectively,
wherein the first gas pipe is connected to the first gas distribution flow path portion,
the first gas distribution flow path portion comprises a plurality of first through-holes corresponding to the first gas supply flow path portions, respectively, and
the first through-holes are connected to the first gas supply flow path portions, respectively.

5. The atomic layer deposition apparatus of claim 4, wherein
The second gas supply flow path portion is provided in plural, and
the second gas supply flow path portions are spaced apart from each other,
wherein the process module further comprises a second gas distribution flow path portion disposed under and connected to the second gas supply flow path portions, wherein the second gas distribution flow path portion divides the second gas into a plurality of flows, and supplies the plurality of flows of the second gas to the second gas supply flow path portions, respectively,
wherein the second gas pipe is connected to the second gas distribution flow path portion,
the second gas distribution flow path portion comprises a plurality of second through-holes corresponding to the second gas supply flow path portions, respectively, and
the second through-holes are connected to the second gas supply flow path portions, respectively.

6. The atomic layer deposition apparatus of claim 5, wherein the second gas supply flow path portions become wider along a direction in which the second gas flows.

7. The atomic layer deposition apparatus of claim 6, further comprising:
a plasma generator disposed on the process area.

8. The atomic layer deposition apparatus of claim 7, wherein the first gas pipe and the second gas pipe are disposed on the first gas supply flow path portion, and a length of the second gas pipe is greater than a length of the first gas pipe.

9. The atomic layer deposition apparatus of claim 6, further comprising:
a gas merging flow path portion disposed on the gas exhaust flow path portion, wherein the gas merging flow path portion concentrates the first gas or the second gas passing through the gas exhaust flow path portion, wherein the exhaust part is connected to the gas merging flow path portion.

10. The atomic layer deposition apparatus of claim 9, wherein the gas merging flow path portion becomes narrower along the direction in which the first gas and the second gas flow.

11. The atomic layer deposition apparatus of claim 2, wherein a thickness of the first gas supply flow path portion and a thickness of the second gas supply flow path portion are smaller than a thickness of the gas exhaust flow path portion.

12. The atomic layer deposition apparatus of claim 11, wherein a sum of the thickness of the first gas supply flow path portion, the thickness of the second gas supply flow path portion, and a thickness of the flow path partitioning portion is substantially the same as the thickness of the gas exhaust flow path portion.

13. The atomic layer deposition apparatus of claim 2, further comprising:
an upper shielding plate disposed on the first gas supply flow path portion,
wherein the first gas supply flow path portion forms a first gas flow path with the upper shielding plate, and
the second gas supply flow path forms a second gas flow path with the substrate support.

14. The atomic layer deposition apparatus of claim 13, wherein
the first gas passes through the first gas flow path,
the second gas passes through the second gas flow path, and
the second gas has a smaller molecular weight than the first gas.

15. An atomic layer deposition method comprising:
preparing an atomic layer deposition apparatus comprising a first gas supply flow path portion to which a first gas and a first purge gas are supplied, a second gas supply flow path portion to which a second gas and a second purge gas are supplied, and a gas exhaust flow path portion from which the first gas and the second gas are discharged;
supplying the first gas to the first gas supply flow path portion;
supplying the first purge gas to the first gas supply flow path portion and stopping the supplying the first gas to the first gas supply flow path portion;
supplying the second gas to the second gas supply flow path portion; and
supplying the second purge gas to the second gas supply flow path portion and stopping the supplying the second gas to the second gas supply flow path portion,
wherein the second gas supply flow path portion is disposed under the first gas supply flow path portion, and
the gas exhaust flow path portion and the first and second gas supply flow path portions are spaced apart from each other.

16. The atomic layer deposition method of claim 15, wherein the first gas and the second gas pass through a process area, which is defined as a space between the gas exhaust flow path portion and the first and second gas supply flow path portions, in a laminar flow pattern.

17. The atomic layer deposition method of claim 16, wherein both the first gas and the first purge gas are present in the process area.

18. The atomic layer deposition method of claim 16, wherein the first gas, the first purge gas, the second gas, and the second purge gas are all present in the process area.

19. The atomic layer deposition method of claim 15, further comprising:
supplying the second purge gas to the second gas supply flow path portion,
wherein the supplying the first gas to the first gas supply flow path portion and the supplying the second purge gas to the second gas supply flow path portion are simultaneously performed.

20. The atomic layer deposition method of claim 19, further comprising:
supplying the first purge gas to the first gas supply flow path portion,
wherein the supplying the second gas to the second gas supply flow path portion and the supplying the first purge gas to the first gas supply flow path portion are simultaneously performed.
